(19) United States
(12) Patent Application Publication
(10) Pub. No.: US 2023/0102417 A1
(43) Pub. Date: Mar. 30, 2023

(54) LIGHT EMITTING ELEMENT SOLVENT, LIGHT EMITTING ELEMENT INK COMPRISING SAME, AND METHOD FOR MANUFACTURING DISPLAY DEVICE

(71) Applicant: Samsung Display Co., LTD., Yongin-si, Gyeonggi-do (KR)

(72) Inventors: Jae Hoon JUNG, Seoul (KR); Buem Joon KIM, Hwaseong-si, Gyeonggi-do (KR); Hee Yeon YOO, Hwaseong-si, Gyeonggi-do (KR); Sung Chan JO, Seoul (KR); Eun A CHO, Suwon-si, Gyeonggi-do (KR); Hye Jung HONG, Cheonan-si, Chungcheongnam-do (KR); Jong Hyuk KANG, Suwon-si, Gyeonggi-do (KR); Keun Kyu SONG, Seongnam-si, Gyeonggi-do (KR); Hyun Deok IM, Seoul (KR); Hyun Min CHO, Seoul (KR)

(73) Assignee: Samsung Display Co., LTD., Yongin-si, Gyeonggi-do (KR)

(21) Appl. No.: 17/792,943

(22) PCT Filed: Jan. 14, 2021
(86) PCT No.: PCT/KR2021/000536

§ 371 Date: Jul. 14, 2022

(30) Foreign Application Priority Data
Jan. 15, 2020 (KR) 10-2020-0005386
Feb. 10, 2020 (KR) 10-2020-0015855

(51) Int. Cl. C09D 11/033; C09D 11/36; C09D 11/50; H01L 51/56; C09K 11/06

(52) U.S. Cl. CPC C09D 11/033; C09D 11/36; C09D 11/50; H01L 51/56; C09K 11/06

(57) ABSTRACT

A light emitting element ink includes a light emitting element solvent, and a light emitting element dispersed in the light-emitting diode solvent. The light emitting element includes semiconductor layers and an insulating film surrounding the outer surface of the semiconductor layers, wherein the light-emitting diode solvent is an organic solvent having a pKa value in a range of about 7 to about 15.

### CROSS-REFERENCE TO RELATED APPLICATION(S)

This application is a national entry of International Application No. PCT/KR2021/000536, filed on Jan. 14, 2021, which claims under 35 U.S.C. §§ 119(a) and 365(b) priority to and benefits of Korean Patent Application No. 10-2020-0005386 filed on Jan. 15, 2020 and No. 10-2020-0015855 filed on Feb. 10, 2020 in the Korean Intellectual Property Office (KIPO), the entire contents of which are incorporated herein by reference.

### BACKGROUND

### 1. Technical Field

The disclosure relates to a light-emitting diode solvent, a light-emitting diode ink comprising the same and method for manufacturing display.

### 2. Description of Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

A display device including an inorganic light emitting diode may be manufactured by an inkjet printing process for dispersing light emitting elements having a small size in an ink and spraying the ink onto an electrode. The light emitting element may be sprayed onto the electrode while being dispersed in a solvent, and may be mounted on the electrode while the position and orientation direction thereof are being changed by the electric field generated on the electrode.

The light emitting element dispersed in the solvent may have a zeta potential due to a double layer formed by solvent molecules and ions included in the solvent that surround the surface of the light emitting element. The light emitting elements may be disposed on the electrode while being aggregated with different light emitting elements depending on the zeta potential while the positions of the light emitting elements are being changed by the electric field. Since the contact between the aggregated light emitting elements and the electrode is poor, an electric signal may not be transmitted to some light emitting elements and, thus, they may not emit light.

### SUMMARY

Aspects of the disclosure provide a light emitting element solvent that allows the zeta potential of the light emitting element to have a value of a certain level or higher and a light emitting element ink.

Aspects of the disclosure also provide a method for manufacturing a display device using the light emitting element ink.

It should be noted that aspects of the disclosure are not limited thereto and other aspects, which are not mentioned herein, will be apparent to those of ordinary skill in the art from the following description.

According to an embodiment of the disclosure, a light emitting element ink comprises a light emitting element solvent, and a light emitting element dispersed in the light emitting element solvent and comprising semiconductor layers and an insulating film surrounding outer surfaces of the semiconductor layers, wherein the light emitting element solvent is an organic solvent having a pKa value in a range of about 7 to about 15.

A zeta potential of the light emitting element dispersed in the light emitting element solvent may satisfy the following Equation 1:

Zeta potential (mV) of the light emitting element dispersed in the light emitting element solvent=C1*pKa+C2, [Equation 1]

wherein the pKa is the pKa value of the light emitting element solvent, the C1 is a real number of 7 to 18, and the C2 is a real number of about −150 to about −300.

The zeta potential of the light emitting element dispersed in the light emitting element solvent may be in a range of about −80 mV to about −50 mV.

The semiconductor layers may comprise a first semiconductor layer, a second semiconductor layer, and an active layer disposed between the first semiconductor layer and the second semiconductor layer, the insulating layer is disposed to surround at least an outer surface of the active layer.

The light emitting element solvent may have a viscosity in a range of about 5 cp to about 80 cp.

The light emitting element solvent may comprise a primary alcohol group.

The light emitting element solvent may comprise a compound represented by the following Chemical Formula 1 or Chemical Formula 2:

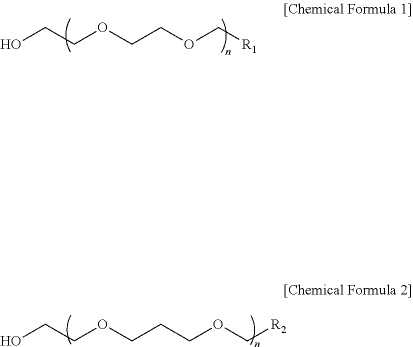

wherein the n is an integer of 2 to 10, and each of the R₁ and the R₂ is independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

The light emitting element solvent may comprise a compound represented by the following Chemical Formula 3:

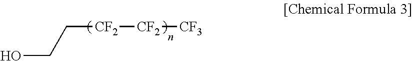

wherein then is an integer of about 1 to about 10.

The light emitting element solvent may comprise a compound represented by any one of the following Chemical Formulas 4 to 6:

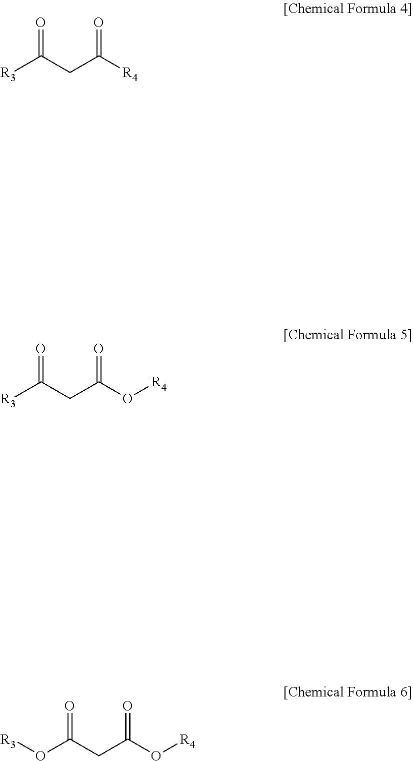

wherein each of the R₃ and R₄ is independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

According to an embodiment of the disclosure, a light emitting element solvent comprises a primary alcohol group having a pKa value in a range of about 7 to about 15 and comprising a compound represented by any one of the Chemical Formula 1 to 3.

The light emitting element solvent may have a viscosity in a range of about 5 cp to about 80 cp.

According to an embodiment of the disclosure, a method for manufacturing a display device, comprises preparing a target substrate on which a first electrode and a second electrode are formed, a light emitting element comprising semiconductor layers, and a light emitting element ink comprising a light emitting element solvent in which the light emitting element is dispersed and which has a pKa value in a range of about 7 to about 15, spraying the light emitting element ink onto the target substrate and generating an electric field on the target substrate, and disposing the light emitting elements on the first electrode and the second electrode.

The light emitting element solvent may comprise a primary alcohol group, and a compound represented by the Chemical Formula 1 or Chemical Formula 2.

A zeta potential of the light emitting element dispersed in the light emitting element solvent may satisfy the Equation 1.

The zeta potential of the light emitting element dispersed in the light emitting element solvent may be in a range of about −80 mV to about −50 mV.

The disposing of the light emitting elements on the first electrode and the second electrode may comprise changing a position and orientation direction of the light emitting element by the electric field.

At least part of the light emitting elements and other part of the light emitting elements may move while repelling each other by a repulsive force acting therebetween.

An end of each of the light emitting elements is disposed on the first electrode, and the other end thereof may be disposed on the second electrode while being spaced apart from each other.

The disposing of the light emitting elements may further comprise removing the light emitting element solvent.

The removing of the light emitting element solvent may be performed through a heat treatment process in a temperature range of about 200° C. to about 400° C.

The details of other embodiments are included in the detailed description and the accompanying drawings.

The light emitting element solvent according to one embodiment may include solvent molecules having a low pKa value, so that the average of the absolute values of the zeta potentials of the light emitting elements dispersed therein may be large. The light emitting elements dispersed in the light emitting element solvent may be maintained in a dispersed state due to the repulsive force acting therebetween.

Further, by manufacturing the display device using the light emitting element ink including the light emitting element and the light emitting element solvent, it is possible to prevent the aggregation of the light emitting elements. In the display device, the light emitting elements are disposed to be spaced apart from each other, so that it is possible to prevent connection failure between the light emitting elements and the electrode.

The effects according to the embodiments are not limited by the contents exemplified above, and more various effects are included in this disclosure.

### BRIEF DESCRIPTION OF DRAWINGS

FIG. 1 is a schematic plan view of a display device according to an embodiment.

FIG. 2 is a schematic plan view illustrating one pixel of a display device according to an embodiment.

FIG. 3 is a schematic cross-sectional view taken along lines and IIIc-IIIc′ of FIG. 2.

FIG. 4 is a schematic cross-sectional view illustrating a portion of a display device according to another embodiment.

FIG. 5 is a schematic diagram of a light emitting element according to an embodiment.

FIGS. 6 and 7 are schematic diagrams of a light emitting element according to another embodiment.

FIG. 8 is a schematic diagram of a light emitting element ink according to an embodiment.

FIG. 9 is a schematic diagram illustrating the light emitting element dispersed in a light emitting element ink according to an embodiment.

FIG. 10 is a flowchart showing a method for manufacturing a display device according to an embodiment.

FIGS. 11 to 14 are schematic views illustrating a part of a manufacturing process of a display device according to an embodiment.

FIG. 15 is a schematic diagram illustrating behavior of a light emitting element in a light emitting element ink according to an embodiment.

FIG. 16 is a graph showing the aggregation ratio of light emitting elements with respect to the zeta potential of the light emitting element in a light emitting element ink according to an embodiment.

FIGS. 17 and 18 are schematic views illustrating a part of a manufacturing process of a display device according to an embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will convey the scope of the disclosure to those skilled in the art.

It will also be understood that when a layer is referred to as being “on” another layer or substrate, it can be directly on the other layer or substrate, or intervening layers may also be present. It will be understood that the terms “contact,” “connected to,” and “coupled to” may include a physical and/or electrical contact, connection, or coupling. The same reference numbers indicate the same components throughout the specification.

It will be understood that, although the terms “first,” “second,” and the like may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

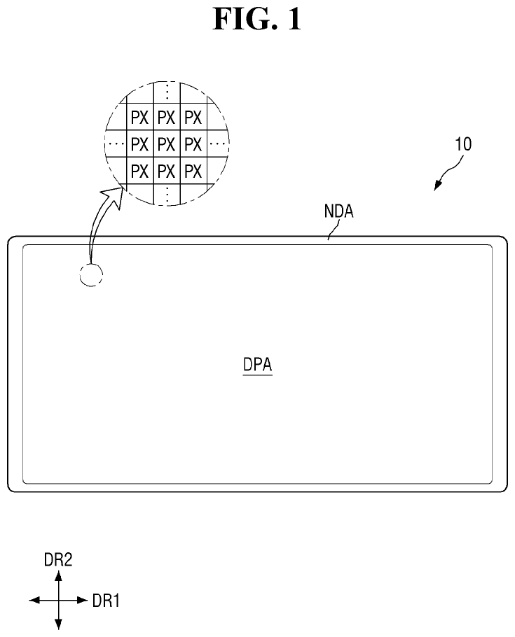

FIG. 1 is a schematic plan view of a display device according to an embodiment.

Referring to FIG. 1, a display device 10 displays a moving image or a still image. The display device 10 may refer to any electronic device providing a display screen. Examples of the display device 10 may include a television, a laptop computer, a monitor, a billboard, an Internet-of-Things (IoT) device, a mobile phone, a smartphone, a tablet personal computer (PC), an electronic watch, a smartwatch, a watch phone, a head-mounted display, a mobile communication terminal, an electronic notebook, an electronic-book reader, a portable multimedia player (PMP), a navigation device, a game machine, a digital camera, a camcorder, and the like, which provide a display screen.

The display device 10 includes a display panel which provides a display screen. Examples of the display panel may include an inorganic light emitting diode display panel, an organic light emitting display panel, a quantum dot light emitting display panel, a plasma display panel, and a field emission display panel. In the following description, a case where an inorganic light emitting diode display panel is applied as a display panel will be exemplified, but the disclosure is not limited thereto, and other display panels may be applied within the same scope of technical spirit.

The shape of the display device 10 may be variously modified. For example, the display device 10 may have shapes such as a rectangular shape elongated in a horizontal direction, a rectangular shape elongated in a vertical direction, a square shape, a quadrilateral shape with rounded corners (vertices), another polygonal shape and a circular shape. The shape of a display area DPA of the display device 10 may also be similar to the overall shape of the display device 10. FIG. 1 illustrates the display device 10 and the display area DPA having a rectangular shape elongated in the horizontal direction.

The display device 10 may include the display area DPA and a non-display area NDA. The display area DPA is an area where an image can be displayed, and the non-display area NDA is an area where an image is not displayed. The display area DPA may also be referred to as an active region, and the non-display area NDA may also be referred to as a non-active region. The display area DPA may substantially occupy the center of the display device 10.

The display area DPA may include pixels PX. The pixels PX may be arranged in a matrix. The shape of each pixel PX may be a rectangular or square shape in a plan view. However, the disclosure is not limited thereto, and it may be a rhombic shape in which each side is inclined with respect to a direction. The pixels PX may be alternately arranged in a stripe type or a PenTile® type. In addition, each of the pixels PX may include one or more light emitting elements 30 that emit light of a specific wavelength band to display a specific color.

The non-display area NDA may be disposed around the display area DPA. The non-display area NDA may completely or partially surround the display area DPA. The display area DPA may have a rectangular shape, and the non-display area NDA may be disposed adjacent to four sides of the display area DPA. The non-display area NDA may form a bezel of the display device 10. Wires or circuit drivers included in the display device 10 may be disposed, or external devices may be mounted, in the non-display area NDA.

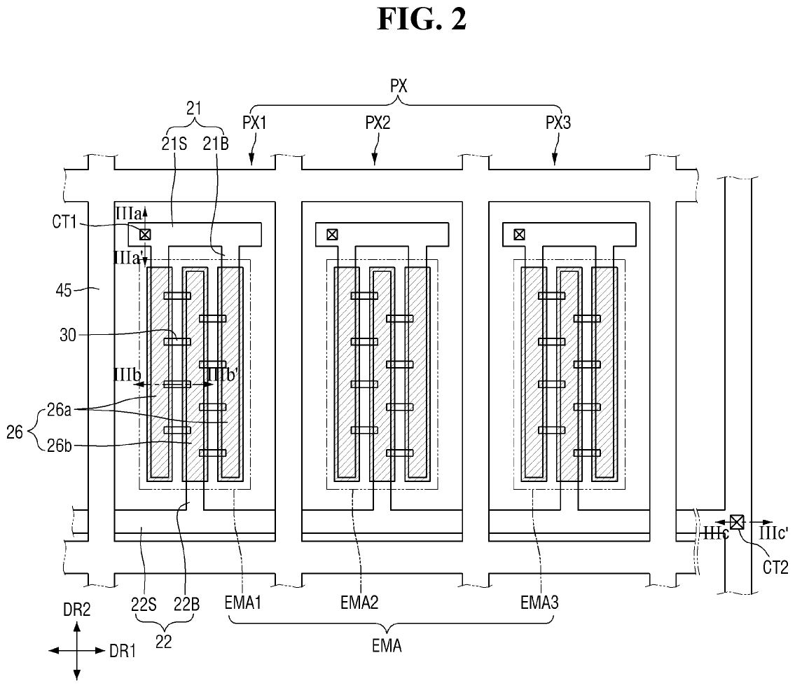

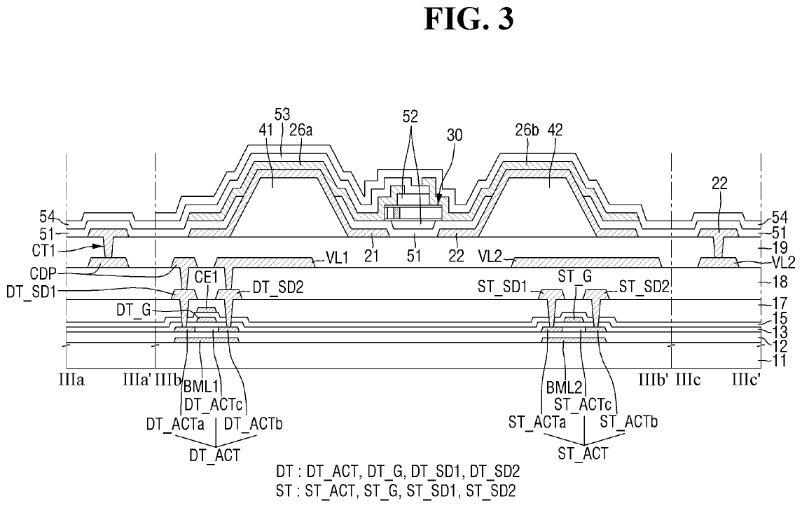

FIG. 2 is a schematic plan view illustrating a pixel of a display device according to an embodiment. FIG. 3 is a schematic cross-sectional view taken along lines IIIc-IIIc′ IIIb-IIIb′ and IIIc-IIIc′ of FIG. 2.

Referring to FIG. 2, each of the pixels PX may include sub-pixels PXn (where n is an integer of about 1 to about 3). For example, a pixel PX may include a first sub-pixel PX1, a second sub-pixel PX2 and a third sub-pixel PX3. The first sub-pixel PX1 may emit light of a first color, the second sub-pixel PX2 may emit light of a second color, and the third sub-pixel PX3 may emit light of a third color. The first color may be blue, the second color may be green, and the third color may be red. However, the disclosure is not limited thereto, and the sub-pixels PXn may emit light of a same color. In addition, although FIG. 2 illustrates that the pixel PX includes three sub-pixels PXn, the disclosure is not limited thereto, and the pixel PX may include a larger number of sub-pixels PXn.

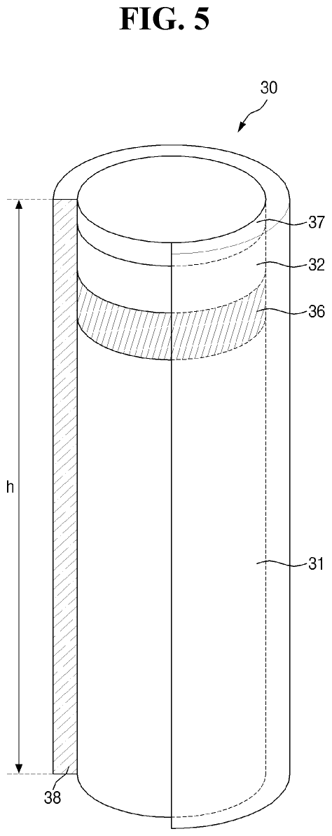

Each sub-pixel PXn of the display device 10 may include a region defined as an emission area EMA. The first sub-pixel PX1 may include a first emission area EMA1, the second sub-pixel PX2 may include a second emission area EMA2, and the third sub-pixel PX3 may include a third emission area EMA3. The emission area EMA may be defined as a region where the light emitting elements 30 included in the display device 10 are disposed to emit light of a specific wavelength band. The light emitting element 30 includes an active layer 36 (see FIG. 5), and the active layer 36 may emit light of a specific wavelength band without directionality. The lights emitted from the active layer 36 of the light emitting element 30 may be emitted in both lateral directions of the light emitting element 30. The emission region EMA may include an area in which the light emitting element 30 is disposed, and an area adjacent to the light emitting element 30 to emit lights emitted from the light emitting element 30.

Without being limited thereto, the emission region EMA may also include an area in which light emitted from the light emitting element 30 is reflected or refracted by another member and emitted. The light emitting elements 30 may be disposed in the respective sub-pixels PXn, and the emission region EMA may be formed to include an area where the light emitting element 30 is disposed and an area which is adjacent thereto.

Although not illustrated in the drawing, each sub-pixel PXn of the display device 10 may include a non-emission area defined as a region other than the emission area EMA. The non-emission area may be a region in which the light emitting element 30 is not disposed and a region from which light is not emitted because light emitted from the light emitting element 30 does not reach it.

FIG. 3 illustrates a cross section of the first sub-pixel PX1 of FIG. 2, but the same may be applied to other pixels PX or sub-pixels PXn. FIG. 3 illustrates a cross section passing through one end and another end of the light emitting element 30 disposed in the first sub-pixel PX1 of FIG. 2.

Referring to FIGS. 2 and 3, the display device 10 may include a first substrate 11, and a circuit element layer and a display element layer disposed on the first substrate 11. A semiconductor layer, conductive layers, and insulating layers are disposed on the first substrate 11, and these may constitute a circuit element layer and a display element layer. The conductive layers may include a first gate conductive layer, a second gate conductive layer, a first data conductive layer, and a second data conductive layer disposed under a first planarization layer 19 to form a circuit element layer, and electrodes 21 and 22 and contact electrodes 26 disposed on the planarization layer 19 to constitute a display element layer. The insulating layers may include a buffer layer 12, a first gate insulating layer 13, a first protective layer 15, a first interlayer insulating layer 17, a second interlayer insulating layer 18, a first planarization layer 19, a first insulating layer 51, a second insulating layer 52, a third insulating layer 53, a fourth insulating layer 54, and the like.

Specifically, the first substrate 11 may be an insulating substrate. The first substrate 11 may be made of an insulating material such as glass, quartz, or polymer resin. Further, the first substrate 11 may be a rigid substrate, but may also be a flexible substrate which can be bent, folded, or rolled.

Light blocking layers BML1 and BML2 may be disposed on the first substrate 11. The light blocking layers BML1 and BML2 may include a first light blocking layer BML1 and a second light blocking layer BML2. The first light blocking layer BML1 and the second light blocking layer BML2 are disposed to overlap at least a first active layer (or first active material layer) DT_ACT of a driving transistor DT and a second active layer (or second active material layer) ST_ACT of a switching transistor ST, respectively. The light blocking layers BML1 and BML2 may include a material blocking light, thereby preventing light from entering the first and second active layers DT_ACT and ST_ACT. For example, the first and second light blocking layers BML1 and BML2 may be formed of an opaque metal material that blocks light transmission. However, the disclosure is not limited thereto, and in some embodiments, the light blocking layers BML1 and BML2 may be omitted.

The buffer layer 12 may be entirely disposed on the light blocking layers BML1 and BML2 and the first substrate 11. The buffer layer 12 may be formed on the first substrate 11 to protect the transistors DT and ST of the pixel PX from moisture penetrating through the first substrate 11 susceptible to moisture permeation, and may perform a surface planarization function. The buffer layer 12 may be formed as (or formed of) inorganic layers that are alternately stacked each other. For example, the buffer layer 12 may be formed as a multilayer in which inorganic layers including at least one of silicon oxide (SiOₓ), silicon nitride (SiNₓ), and silicon oxynitride (SiOₓN_{y}) are alternately stacked each other.

The semiconductor layer is disposed on the buffer layer 12. The semiconductor layer may include the first active layer DT_ACT of the driving transistor DT and the second active layer ST_ACT of the switching transistor ST. These may be disposed to partially overlap gate electrodes DT_G and ST_G of the first gate conductive layer, which will be described below.

In an embodiment, the semiconductor layer may include polycrystalline silicon, monocrystalline silicon, oxide semiconductor, or the like. The polycrystalline silicon may be formed by crystallizing amorphous silicon. In case that the semiconductor layer includes polycrystalline silicon, the first active layer DT_ACT may include a first doped region DT_ACTa, a second doped region DT_ACTb, and a first channel region DT_ACTc. The first channel region DT_ACTc may be disposed between the first doped region DT_ACTa and the second doped region DT_ACTb. The second active layer ST_ACT may include a third doped region ST_ACTa, a fourth doped region ST_ACTb, and a second channel region ST_ACTc. The second channel region ST_ACTc may be disposed between the third doped region ST_ACTa and the fourth doped region ST_ACTb. The first doped region DT_ACTa, the second doped region DT_ACTb, the third doped region ST_ACTa, and the fourth doped region ST_ACTb may be regions formed by doping some regions of the first active layer DT_ACT and the second active layer ST_ACT with impurities.

In an embodiment, the first active layer DT_ACT and the second active layer ST_ACT may include an oxide semiconductor. In this case, the doped regions of the first active layer DT_ACT and the second active layer ST_ACT may be conductor regions, respectively. The oxide semiconductor may be an oxide semiconductor containing indium (In). In some embodiments, the oxide semiconductor may be indium tin oxide (ITO), indium zinc oxide (IZO), indium gallium oxide (IGO), indium zinc tin oxide (IZTO), indium gallium tin oxide (IGTO), indium gallium zinc tin oxide (IGZTO) or the like. However, the disclosure is not limited thereto.

The first gate insulating layer 13 is disposed on the semiconductor layer and the buffer layer 12. The first gate insulating layer 13 may function as a gate insulating layer of the driving transistor DT and the switching transistor ST. The first gate insulating layer 13 may be formed as an inorganic layer including an inorganic material such as silicon oxide (SiOₓ), silicon nitride (SiNₓ), or silicon oxynitride (SiOₓN_{y}), or a stacked structure thereof.

The first gate conductive layer is disposed on the first gate insulating layer 13. The first gate conductive layer may include a first gate electrode DT_G of the driving transistor DT and a second gate electrode ST_G of the switching transistor ST. The first gate electrode DT_G may be disposed to overlap the first channel region DT_ACTc of the first active layer DT_ACT in a thickness direction, and the second gate electrode ST_G may be disposed to overlap the second channel region ST_ACTc of the second active layer ST_ACT in the thickness direction.

The first gate conductive layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the disclosure is not limited thereto.

The first protective layer 15 is disposed on the first gate conductive layer. The first protective layer 15 may be disposed to cover the first gate conductive layer to function to protect it. The first protective layer 15 may be formed as an inorganic layer including an inorganic material such as silicon oxide (SiOₓ), silicon nitride (SiNₓ), or silicon oxynitride (SiOₓN_{y}), or a stacked structure thereof.

The second gate conductive layer is disposed on the first protective layer 15. The second gate conductive layer may include a first capacitive electrode CE1 of a storage capacitor disposed to at least partially overlap the first gate electrode DT_G in the thickness direction. The first capacitive electrode CE1 overlaps the first gate electrode DT_G in the thickness direction with the first protective layer 15 interposed therebetween, and a storage capacitor may be formed between them. The second gate conductive layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the disclosure is not limited thereto.

The first interlayer insulating layer 17 is disposed on the second gate conductive layer. The first interlayer insulating layer 17 may function as an insulating layer between the second gate conductive layer and other layers disposed thereon. The first interlayer insulating layer 17 may be formed as an inorganic layer including an inorganic material such as silicon oxide (SiOₓ), silicon nitride (SiNₓ), or silicon oxynitride (SiOₓN_{y}), or a stacked structure thereof.

The first data conductive layer is disposed on the first interlayer insulating layer 17. The first gate conductive layer may include a first source/drain electrode DT_SD1 and a second source/drain electrode DT_SD2 of the driving transistor DT, and a first source/drain electrode ST_SD1 and the second source/drain electrode ST_SD2 of the switching transistor ST.

The first source/drain electrode DT_SD1 and the second source/drain electrode DT_SD2 of the driving transistor DT may contact (or may be in contact with) the first doped region DT_ACTa and the second doped region DT_ACTb of the first active layer DT_ACT through contact holes passing through the first interlayer insulating layer 17 and the first gate insulating layer 13, respectively. The first source/drain electrode ST_SD1 and the second source/drain electrode ST_SD2 of the switching transistor ST may contact the third doped region ST_ACTa and the fourth doped region ST_ACTb of the second active layer ST_ACT through contact holes passing through the first interlayer insulating layer 17 and the first gate insulating layer 13, respectively. Further, the first source/drain electrode DT_SD1 of the driving transistor DT and the first source/drain electrode ST_SD1 of the switching transistor ST may be electrically connected to the first light blocking layer BML1 and the second light blocking layer BML2, respectively, through other contact holes. In the first source/drain electrodes DT_SD1, ST_SD1 and the second source/drain electrodes DT_SD2, ST_SD2 of the driving transistor DT and the switching transistor ST, in case that an electrode is a source electrode, the other electrode may be a drain electrode. However, the disclosure is not limited thereto, and in the first source or drain electrode DT_SD1 and the second source or drain electrode DT_SD2 and the first source or drain electrode ST_SD1 and the second source or drain electrode ST_SD2, in case that an electrode is a drain electrode, the other electrode may be a source electrode.

The first data conductive layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the disclosure is not limited thereto.

The second interlayer insulating layer 18 may be disposed on the first data conductive layer. The second interlayer insulating layer 18 is disposed entirely on the first interlayer insulating layer 17 to cover the first data conductive layer, and may function to protect the first data conductive layer. The second interlayer insulating layer 18 may be formed as an inorganic layer including an inorganic material such as silicon oxide (SiOₓ), silicon nitride (SiNₓ), or silicon oxynitride (SiOₓN_{y}), or a stacked structure thereof.

The second data conductive layer is disposed on the second interlayer insulating layer 18. The second data conductive layer may include a first voltage line VL1, a second voltage line VL2, and a first conductive pattern CDP. The first voltage line VL1 may be applied with a high-potential voltage (or a first source voltage) supplied to the driving transistor DT, and the second voltage line VL2 may be applied with a low-potential voltage (or a second source voltage) supplied to the second electrode 22. During the process of manufacturing the display device 10, the second voltage line VL2 may be applied with an alignment signal required to align the light emitting element 30.

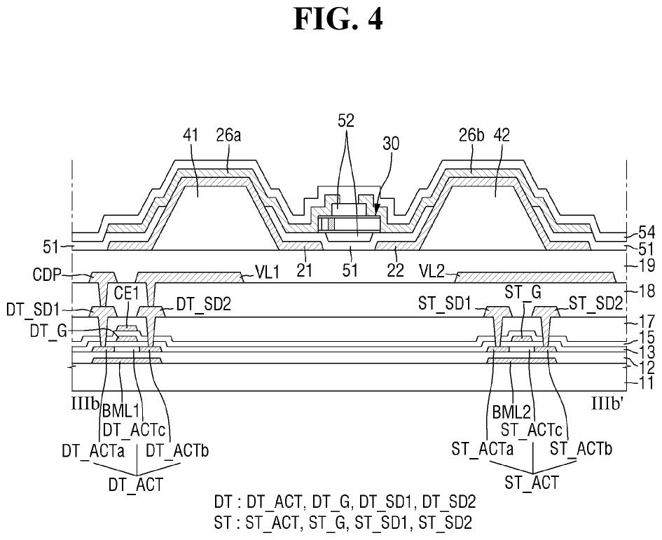

The first conductive pattern CDP may be electrically connected to the first source/drain electrode DT_SD1 of the driving transistor DT through the contact hole formed in the second interlayer insulating layer 18. The first conductive pattern CDP may also contact the first electrode 21 to be described below, and the driving transistor DT may transfer the first source voltage, applied from the first voltage line VL1, to the first electrode 21 through the first conductive pattern CDP. Although FIGS. 3 and 4 illustrate that the second data conductive layer includes a second voltage line VL2 and a first voltage line VL1, the disclosure is not limited thereto. The second data conductive layer may include a larger number of first voltage lines VL1 and second voltage lines VL2.

The second data conductive layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the disclosure is not limited thereto.

The first planarization layer 19 is disposed on the second data conductive layer. The first planarization layer 19 may include an organic insulating material, for example, an organic material such as polyimide (PI), to perform a surface planarization function.

Internal banks 41 and 42, the electrodes 21 and 22, an external bank 45, the contact electrodes 26, and the light emitting element 30 are disposed on the first planarization layer 19. In addition, insulating layers 51, 52, 53, and 54 may be further disposed on the first planarization layer 19.

The internal banks 41 and 42 may be disposed directly on the first planarization layer 19. The internal banks 41 and 42 may include a first internal bank 41 and a second internal bank 42 disposed adjacent to the center of each sub-pixel PXn.

The first internal bank 41 and the second internal bank 42 may be spaced apart from each other and disposed to face each other in a first direction DR1. Since the internal banks 41 and 42 are spaced apart from each other and disposed to face each other, a region in which the light emitting element 30 is disposed may be formed therebetween. Further, the first internal bank 41 and the second internal bank 42 may extend in the second direction DR2 within each sub-pixel PXn, but may be separated from those in other sub-pixels PXn adjacent thereto in the second direction DR2 at the boundary between the sub-pixels PXn so as not to extend to the other sub-pixels PXn. Accordingly, the first internal bank 41 and the second internal bank 42 may be disposed for each sub-pixel PXn to form a pattern on the front surface of the display device 10. Although FIG. 3 illustrates only a first internal bank 41 and a second internal bank 42, the disclosure is not limited thereto. A larger number of internal banks 41 and 42 may be further arranged according to the number of electrodes 21 and 22 to be described below.

The first internal bank 41 and the second internal bank 42 may have a structure in which at least part thereof protrudes with respect to the top surface of the first planarization layer 19. The protruding portions of the first internal bank 41 and the second internal bank 42 may have inclined side surfaces, and the light emitted from the light emitting element 30 may travel toward the inclined side surfaces of the internal banks 41 and 42. As will be described below, the electrodes 21 and 22 disposed on the internal banks 41 and 42 may include a material having high reflectivity, and the light emitted from the light emitting element 30 may be reflected from the electrodes 21 and 22 disposed on the side surfaces of the internal banks 41 and 42 and emitted in the upward direction of the first planarization layer 19. For example, the internal banks 41 and 42 may provide a region in which the light emitting elements 30 are disposed, and may also function as a reflective partition wall that reflects light emitted from the light emitting elements 30 upward. In an embodiment, the internal banks 41 and 42 may include an organic insulating material such as polyimide (PI), but are not limited thereto.

The electrodes 21 and 22 are disposed on the internal banks 41 and 42 and the first planarization layer 19. The electrodes 21 and 22 may be electrically connected to the light emitting elements 30, and may be applied with a voltage (e.g., a predetermined or selected voltage) such that the light emitting element 30 emits light in a specific wavelength band. In addition, at least part of each of the electrodes 21 and 22 may be utilized to form an electric field in the sub-pixel PXn to align the light emitting element 30.

The electrodes 21 and 22 may include a first electrode 21 disposed on the first internal bank 41 and a second electrode 22 disposed on the second internal bank 42.

The first electrode 21 and the second electrode 22 may include respective electrode stems 21S and 22S disposed to extend in the first direction DR1, and at least one respective electrode branches 21B and 22B extending in a second direction DR2, which is a direction intersecting the first direction DR1, from the electrode stems 21S and 22S, and branched off therefrom.

The first electrode 21 may include a first electrode stem 21S extending in the first direction DR1 and at least one electrode branch 21B branched off from the first electrode stem 21S and extending in the second direction DR2.

The first electrode stems 21S may be arranged such that ends of the individual first electrode stems 21S are terminated with gaps between the respective sub-pixels PXn, and each first electrode stem 21S may be arranged on substantially the same straight line as the first electrode stem 21S of the sub-pixel adjacent to it in a same row (for example, in the first direction DR1). Since the first electrode stems 21S disposed in the respective sub-pixels PXn are arranged such that ends thereof are spaced apart from each other, it may be possible to apply different electric signals to the first electrode branches 21B, so that the first electrode branches 21B may be driven individually. The first electrode 21 may contact the first conductive pattern CDP through a first contact hole CT1 penetrating the first planarization layer 19, and thus may be electrically connected to a first source/drain DT_SD1 of the driving transistor DT.

The first electrode branch 21B may be branched from at least part of the first electrode stem 21S and be disposed to extend in the second direction DR2, and may be terminated while being spaced apart from the second electrode stem 22S disposed to face the first electrode stem 21S.

The second electrode 22 may include a second electrode stem 22S extending in the first direction DR1 and disposed to face the first electrode stem 21S while being distanced apart from it in the second direction DR2, and a second electrode branch 22B branched off from the second electrode stem 22S and extending in the second direction DR2.

The second electrode stem 22S may extend in the first direction DR1 and may be disposed beyond the boundary of another adjacent sub-pixel PXn. The second electrode stem 22S elongated across the sub-pixels PXn may be connected to an outer part of the display area DPA or a portion extending in a direction in the non-display area NDA. The second electrode 22 may contact the second voltage line VL2 through a second contact hole CT2 penetrating the first planarization layer 19. As illustrated in the drawing, the second electrodes 22 of the sub-pixels PXn adjacent to each other in the first direction DR1 may be connected to a second electrode stem 22S and thus may be electrically connected to the second voltage line VL2 through the second contact hole CT2. However, the disclosure is not limited thereto, and in some embodiments, even the second contact hole CT2 may be formed for each sub-pixel PXn.

The second electrode branch 22B may be spaced apart from and face the first electrode branch 21B, and may be terminated while being spaced apart from the first electrode stem 21S. The second electrode branch 22B may be connected to the second electrode stem 22S, and an end thereof in an extended direction may be disposed in the sub-pixel PXn while being spaced apart from the first electrode stem 21S.

Although FIG. 2 illustrates that two first electrode branches 21B and a second electrode branch 22B are disposed in each sub-pixel PXn, the disclosure is not limited thereto. In some embodiments, a larger number of first electrode branches 21B and second electrode branches 22B may be disposed in each sub-pixel PXn. In addition, the first electrode 21 and the second electrode 22 disposed in each sub-pixel PXn may not necessarily have a shape extending in a direction, and the first electrode 21 and the second electrode 22 may be arranged in various structures. For example, the first electrode 21 and the second electrode 22 may have a partially curved or bent shape, and an electrode thereof may be disposed to surround the other electrode. At least some regions of the first electrode 21 and the second electrode 22 are spaced apart from each other to face each other. Accordingly, an arrangement structure or shape thereof is not particularly limited as long as a region where the light emitting element 30 is to be disposed is formed therebetween.

The first electrode 21 and the second electrode 22 may be disposed on the first internal bank 41 and the second internal bank 42, respectively, and they may be spaced apart from each other and face each other. In the first electrode 21 and the second electrode 22, the electrode branches 21B and 22B may be disposed on the first internal bank 41 and the second internal bank 42, respectively, and at least some regions thereof may be disposed directly on the planarization layer 19. At least one end of each of the light emitting elements 30 disposed between the first internal bank 41 and the second internal bank 42 may be electrically connected to the first electrode 21 and the second electrode 22.

Each of the electrodes 21 and 22 may include a transparent conductive material. For example, each of the electrodes 21 and 22 may include a material such as indium tin oxide (ITO), indium zinc oxide (IZO), or indium tin zinc oxide (ITZO), but is not limited thereto. In some embodiments, each of the electrodes 21 and 22 may include a conductive material having high reflectivity. For example, each of the electrodes 21 and 22 may include, as a material having high reflectivity, metal such as silver (Ag), copper (Cu), or aluminum (Al). In this case, light incident on each of the electrodes 21 and 22 may be reflected and emitted in an upward direction of each sub-pixel PXn.

Further, each of the electrodes 21 and 22 may have a structure in which at least one transparent conductive material and at least one metal layer having high reflectivity are stacked each other, or may be formed as a layer including them. In an embodiment, each of the electrodes 21 and 22 may have a stacked structure of ITO/silver (Ag)/ITO/IZO, or may be an alloy including aluminum (Al), nickel (Ni), lanthanum (La), or the like. However, the disclosure is not limited thereto.

The electrodes 21 and 22 may be electrically connected to the light emitting elements 30 and may be applied with a voltage (e.g., a predetermined or selected) voltage to allow the light emitting elements 30 to emit light. For example, the electrodes 21 and 22 may be electrically connected to the light emitting elements 30 by the contact electrodes 26 to be described below, and the electrical signals applied to the electrodes 21 and 22 may be transferred to the light emitting elements 30 through the contact electrodes 26.

In an embodiment, the first electrode 21 may be a separate electrode for each sub-pixel PXn, and the second electrode 22 may be an electrode commonly connected along each sub-pixel PXn. One of the first electrode 21 and the second electrode 22 may be electrically connected to an anode electrode of the light emitting element 30, and the other one thereof may be electrically connected to a cathode electrode of the light emitting element 30. However, the disclosure is not limited thereto, and an opposite case may also be possible.

Further, each of the electrodes 21 and 22 may be used to form an electric field in the sub-pixel PXn to align the light emitting elements 30. The light emitting element 30 may be disposed between the first electrode 21 and the second electrode 22 by a process of forming an electric field between the first electrode 21 and the second electrode 22 by applying an alignment signal to the first electrode 21 and the second electrode 22. The light emitting element 30 may be sprayed on the first electrode 21 and the second electrode 22 in a state of being dispersed in ink by an inkjet printing process, and may be aligned between the first electrode 21 and the second electrode 22 by applying an alignment signal thereto to apply a dielectrotrophoretic force to the light emitting element 30.

A first insulating layer 51 is disposed on the first planarization layer 19, the first electrode 21, and the second electrode 22. The first insulating layer 51 is disposed to partially cover the first electrode 21 and the second electrode 22. The first insulating layer 51 may be arranged to mostly cover the top surfaces of the first and second electrodes 21 and 22 and partially expose the first and second electrodes 21 and 22. The first insulating layer 51 may be disposed to expose a part of the top surfaces of the first electrode 21 and the second electrode 22, for example, a part of the top surface of the first electrode branch 21B disposed on the first internal bank 41 and the top surface of the second electrode branch 22B disposed on the second internal bank 42. The first insulating layer 51 may be formed substantially on the entire first planarization layer 19, and may include an opening partially exposing the first electrode 21 and the second electrode 22.

In an embodiment, the first insulating layer 51 may be formed to have a step such that a portion of the top surface thereof is recessed between the first electrode 21 and the second electrode 22. In some embodiments, the first insulating layer 51 may include an inorganic insulating material, and a portion of the top surface of the first insulating layer 51 disposed to cover the first electrode 21 and the second electrode 22 may be recessed due to a step of the member disposed therebelow. The light emitting element 30 disposed on the first insulating layer 51 between the first electrode 21 and the second electrode 22 and the recessed top surface of the first insulating layer 51 may have an empty space therebetween. The light emitting element 30 may be disposed partially spaced apart from the top surface of the first insulating layer 51 with a clearance (or empty space) therebetween, and this clearance may be filled with a material forming the second insulating layer 52 to be described below. However, the disclosure is not limited thereto. The first insulating layer 51 may form a flat top surface such that the light emitting element 30 is disposed thereon.

The first insulating layer 51 may protect the first electrode 21 and the second electrode 22 while insulating them from each other. Further, it is possible to prevent the light emitting element 30 disposed on the first insulating layer 51 from being damaged by directly contacting other members. However, the shape and structure of the first insulating layer 51 are not limited thereto.

The external bank 45 may be disposed on the first insulating layer 51. In some embodiments, the external bank 45 may surround an area where the light emitting element 30 is disposed in addition to an area of the first insulating layer 51 where the internal banks 41 and 42 and the electrodes 21 and 22 are disposed, and may be disposed at the boundary between the sub-pixels PXn. The external bank 45 may be disposed to have a shape extending in the first direction DR1 and the second direction DR2, thereby forming a grid pattern in the entire display area DPA.

In accordance with an embodiment, the height of the external bank 45 may be greater than the heights of the internal banks 41 and 42. Unlike the internal banks 41 and 42, the external bank 45 may partition the adjacent sub-pixels PXn and may perform a function of preventing an ink from overflowing to the adjacent sub-pixel PXn in the inkjet printing process for disposing the light emitting element 30 during the manufacturing process of the display device 10 as will be described below. In order not to mix the inks with each other in which the different light emitting elements 30 are dispersed for each of the different sub-pixels PXn, the external bank 45 may separate the inks. Similar to the internal banks 41 and 42, the external bank 45 may include polyimide (PI), but is not limited thereto.

The light emitting element 30 may be disposed between the electrodes 21 and 22. For example, the light emitting element 30 may be disposed between the electrode branches 21B and 22B. The light emitting elements 30 may be disposed to be spaced apart from each other and may be aligned substantially parallel to each other. The distance between the light emitting elements 30 is not particularly limited. In some embodiments, light emitting elements 30 may be arranged adjacently to form a group, and other light emitting elements 30 may be grouped while being spaced apart at a regular interval, and may be arranged with non-uniform density. In addition, in an embodiment, the light emitting element 30 may have a shape extending in a direction, and the extension direction of the light emitting element 30 may be substantially perpendicular to the extension direction of the electrodes 21 and 22. However, the disclosure is not limited thereto, and the light emitting element 30 may be disposed obliquely without being perpendicular to the extension direction of the electrodes 21 and 22.

The light emitting elements 30 according to an embodiment may have the active layers 36 including different materials, and thus may emit light of different wavelength bands to the outside. The display device 10 may include the light emitting elements 30 that emit light of different wavelength bands. For example, the light emitting element 30 of the first sub-pixel PX1 may include the active layer 36 that emits light of a first color having a central wavelength band of a first wavelength, the light emitting element 30 of the second sub-pixel PX2 may include the active layer 36 that emits light of a second color having a central wavelength band of a second wavelength, and the light emitting element 30 of the third sub-pixel PX3 may include the active layer 36 that emits light of a third color having a central wavelength band of a third wavelength.

Accordingly, light of the first color, light of the second color, and light of the third color may be emitted from the first sub-pixel PX1, the second sub-pixel PX2, and the third sub-pixel PX3, respectively. In some embodiments, the light of the first color may be blue light having a central wavelength band of about 450 nm to about 495 nm, the light of the second color may be green light having a central wavelength band of about 495 nm to about 570 nm, and the light of the third color may be red light having a central wavelength band of about 620 nm to about 752 nm. However, the disclosure is not limited thereto. In some embodiments, the first sub-pixel PX1, the second sub-pixel PX2, and the third sub-pixel PX3 may include the light emitting elements 30 of a same type to emit light of substantially a same color.

The light emitting element 30 may be disposed on the first insulating layer 51 between the internal banks 41 and 42 or between the electrodes 21 and 22. For example, the light emitting element 30 may be disposed on the first insulating layer 51 disposed between the internal banks 41 and 42. The light emitting element 30 may be disposed to partially overlap the electrodes 21 and 22 in the thickness direction. An end of the light emitting element 30 may be disposed on the first electrode 21 while overlapping the first electrode 21 in the thickness direction, and another end thereof may be disposed on the second electrode 22 while overlapping the second electrode 22 in the thickness direction. However, the disclosure is not limited thereto. Although not shown in the drawing, at least some of the light emitting elements 30 disposed in each sub-pixel PXn may be disposed in an area other than the area between the internal banks 41 and 42, e.g., an area other than the area between the electrode branches 21B and 22B, or between the internal banks 41 and 42 and the external bank 45.

The light emitting element 30 may be provided with layers disposed in a direction perpendicular to the top surface of the first substrate 11 or the first planarization layer 19. According to an embodiment, the light emitting element 30 may have a shape extending in a direction and may have a structure in which semiconductor layers are sequentially arranged in a direction. The light emitting element 30 of the display device 10 may be disposed such that an extension direction is parallel to the first planarization layer 19, and the semiconductor layers included in the light emitting element 30 may be sequentially arranged in a direction parallel to the top surface of the first planarization layer 19. However, the disclosure is not limited thereto. In some embodiments, in case that the light emitting element 30 has a different structure, layers may be arranged in a direction perpendicular to the first planarization layer 19.

In addition, an end of the light emitting element 30 may contact the first contact electrode 26a, and another end thereof may contact the second contact electrode 26b. In accordance with an embodiment, an insulating film 38 (see FIG. 5) is not formed on the end surface of the light emitting element 30 in its extension direction and the semiconductor layer is partially exposed, so that the exposed semiconductor layer may contact the first contact electrode 26a and the second contact electrode 26b to be described below. However, the disclosure is not limited thereto. In some embodiments, in the light emitting element 30, at least part of the insulating film 38 is removed, so that the side surfaces at both ends of the semiconductor layers may be partially exposed.

The second insulating layer 52 may be partially disposed on the light emitting element 30 disposed between the first electrode 21 and the second electrode 22. The second insulating layer 52 may be disposed to partially surround the outer surface of the light emitting element 30. A portion of the second insulating layer 52 disposed on the light emitting element 30 may have a shape extending in the second direction DR2 between the first electrode 21 and the second electrode 22 in a plan view. For example, the second insulating layer 52 may form a stripe-type or island-type pattern in each sub-pixel PXn.

The second insulating layer 52 may be disposed on the light emitting element 30 to expose an end and another end of the light emitting element 30. The exposed ends of the light emitting element 30 may contact the contact electrodes 26 to be described below. The shape of the second insulating layer 52 may be formed by a patterning process using a material forming the second insulating layer 52 and using a conventional mask process. The mask for forming the second insulating layer 52 may have a width smaller than the length of the light emitting element 30, and the material forming the second insulating layer 52 may be patterned such that ends of the light emitting element 30 are exposed. However, the disclosure is not limited thereto.

The second insulating layer 52 may function to protect the light emitting element 30 and also fix the light emitting element 30 in a manufacturing process of the display device 10. Further, in an embodiment, a portion of the material of the second insulating layer 52 may be disposed between the bottom surface of the light emitting element 30 and the first insulating layer 51. As described above, the second insulating layer 52 may be formed to fill a space between the first insulating layer 51 and the light emitting element 30 formed during the manufacturing process of the display device 10. Accordingly, the second insulating layer 52 may be disposed to surround the outer surface of the light emitting element 30 to protect the light emitting element 30 and also fix the light emitting element 30 during the manufacturing process of the display device 10.

The contact electrodes 26 are disposed on the first electrode 21, the second electrode 22, and the second insulating layer 52. Further, the third insulating layer 53 may be disposed on any one contact electrodes 26.

The contact electrodes 26 may have a shape extending in a direction. The contact electrodes 26 may contact the light emitting element 30 and the electrodes 21 and 22, and the light emitting elements 30 may receive electrical signals from the first electrode 21 and the second electrode 22 through the contact electrode 26.

The contact electrode 26 may include a first contact electrode 26a and a second contact electrode 26b. The first contact electrode 26a and the second contact electrode 26b may be disposed on the first electrode 21 and the second electrode 22, respectively. Each of the first contact electrode 26a and the second contact electrode 26b may have a shape extending in the second direction DR2. The first contact electrode 26a and the second contact electrode 26b may be disposed opposite to each other with a space therebetween in the first direction DR1, and they may form striped patterns in the emission area EMA of each sub-pixel PXn.

In some embodiments, the widths of the first contact electrode 26a and the second contact electrode 26b measured in a direction may be equal to or greater than the widths of the first electrode 21 and the second electrode 22 measured in the a direction, respectively. The first contact electrode 26a and the second contact electrode 26b may be disposed not only to contact an end and another end of the light emitting element 30, respectively, but also to cover side surfaces of the first electrode 21 and the second electrode 22, respectively. Further, at least regions of the first contact electrode 26a and the second contact electrode 26b may be disposed on the first insulating layer 51. Further, at least some regions of the first contact electrode 26a and the second contact electrode 26b may be disposed on the second insulating layer 52. The first contact electrode 26a may be disposed directly on the second insulating layer 52, and the second contact electrode 26b may be disposed directly on the third insulating layer 53 disposed on the first contact electrode 26a and may overlap the second insulating layer 52. However, the disclosure is not limited thereto, and the third insulating layer 53 may be omitted so that the second contact electrode 26b may be disposed directly on the second insulating layer 52.

As described above, the top surfaces of the first electrode 21 and the second electrode 22 may be partially exposed, and the first contact electrode 26a and the second contact electrode 26b may contact the exposed top surfaces of the first electrode 21 and the second electrode 26b. For example, the first contact electrode 26a may contact a portion of the first electrode 21 positioned on the first internal bank 41, and the second contact electrode 26b may contact a portion of the second electrode 22 positioned on the second internal bank 42. However, the disclosure is not limited thereto, and in some embodiments, the first contact electrode 26a and the second contact electrode 26b may be formed to have widths smaller than those of the first electrode 21 and the second electrode 22 and cover only the exposed portions of the top surfaces.

According to an embodiment, in the light emitting element 30, the semiconductor layer may be exposed on end surfaces of the light emitting element 30 in its extension direction, and the first contact electrode 26a and the second contact electrode 26b may contact the end surfaces of the light emitting element 30 on which the semiconductor layer has been exposed. However, the disclosure is not limited thereto. In some embodiments, the semiconductor layers may be exposed at ends of the light emitting element 30, and the contact electrodes 26 may contact the exposed semiconductor layer. An end of the light emitting element 30 may be electrically connected to the first electrode 21 through the first contact electrode 26a, and another end thereof may be electrically connected to the second electrode 22 through the second contact electrode 26b.

Although FIG. 2 illustrates that two first contact electrodes 26a and a second contact electrode 26b are disposed in a sub-pixel PXn, the disclosure is not limited thereto. The number of first contact electrodes 26a and second contact electrodes 26b may vary depending on the number of first electrode branches 21B and second electrode branches 22B disposed in each sub-pixel PXn.

The contact electrode 26 may include a conductive material. For example, the contact electrode 26 may include ITO, IZO, ITZO, aluminum (Al), or the like. As an example, the contact electrodes 26 may include a transparent conductive material, and light emitted from the light emitting element 30 may pass through the contact electrodes 26 and proceed toward the electrodes 21 and 22. Each of the electrodes 21 and 22 may include a material having high reflectivity, and the electrodes 21 and 22 placed on the inclined side surfaces of the internal banks 41 and 42 may reflect incident light in the upward direction of the first substrate 11. However, the disclosure is not limited thereto.

A third insulating layer 53 is disposed on the first contact electrode 26a. The third insulating layer 53 may electrically insulate the first contact electrode 26a and the second contact electrode 26b from each other. The third insulating layer 53 may be disposed to cover the first contact electrode 26a, but may not be disposed on another end of the light emitting element 30 such that the light emitting element 30 can contact the second contact electrode 26b. The third insulating layer 53 may partially contact the first contact electrode 26a and the second insulating layer 52 on the top surface of the second insulating layer 52. The side surface of the third insulating layer 53 in a direction in which the second electrode 22 is disposed may be aligned with a side surface of the second insulating layer 52. In addition, the third insulating layer 53 may be disposed in the non-emission area, e.g., on the first insulating layer 51 disposed on the first planarization layer 19. However, the disclosure is not limited thereto.

The fourth insulating layer 54 may be disposed entirely on the first substrate 11. The fourth insulating layer 54 may function to protect the members disposed on the first substrate 11 against the external environment.

Each of the first insulating layer 51, the second insulating layer 52, the third insulating layer 53, and the fourth insulating layer 54 described above may include an inorganic insulating material or an organic insulating material. In an embodiment, the first insulating layer 51, the second insulating layer 52, the third insulating layer 53, and the fourth insulating layer 54 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlNₓ), and the like. As another example, they may include an organic insulating material such as acrylic resin, epoxy resin, phenolic resin, polyamide resin, polyimide resin, unsaturated polyester resin, polyphenylene resin, polyphenylenesulfide resin, benzocyclobutene, cardo resin, siloxane resin, silsesquioxane resin, polymethylmethacrylate, polycarbonate, polymethylmethacrylate-polycarbonate synthetic resin, and the like. However, the disclosure is not limited thereto.

FIG. 4 is a schematic cross-sectional view illustrating a portion of a display device according to another embodiment.

Referring to FIG. 4, in the display device 10 according to an embodiment, the third insulating layer 53 may be omitted. The second contact electrode 26b may be disposed directly on the second insulating layer 52, and the first contact electrode 26a and the second contact electrode 26b may be disposed on the second insulating layer 52 to be spaced apart from each other. The embodiment of FIG. 4 is the same as the embodiment of FIG. 3 except that the third insulating layer 53 is omitted. Hereinafter, redundant description will be omitted.

The light emitting element 30 may be a light emitting diode. Specifically, the light emitting element 30 may be an inorganic light emitting diode that has a micrometer or nanometer size, and is made of an inorganic material. The inorganic light emitting diode may be aligned between two electrodes having polarity in case that an electric field is formed in a specific direction between two electrodes opposing each other.

FIG. 5 is a schematic diagram of a light emitting element according to an embodiment.

Referring to FIG. 5, the light emitting element 30 according to an embodiment may have a shape extending in a direction. The light emitting element 30 may have a shape of a rod, a wire, a tube, or the like. In an embodiment, the light emitting element 30 may have a cylindrical or rod shape. However, the shape of the light emitting element 30 is not limited thereto, and the light emitting element 30 may have a polygonal prism shape such as a regular cube, a rectangular parallelepiped, and a hexagonal prism, or may have various shapes such as a shape extending in a direction and having an outer surface partially inclined.

The light emitting element 30 may include a semiconductor layer doped with any conductivity type (e.g., p-type or n-type) impurities. The semiconductor layer may emit light of a specific wavelength band by receiving an electrical signal applied from an external power source. Semiconductors included in the light emitting element 30 may have a structure in which they are sequentially arranged or stacked each other in the a direction.

The light emitting element 30 may include a first semiconductor layer 31, a second semiconductor layer 32, an active layer 36, an electrode layer 37, and an insulating layer 38. FIG. 5 illustrates a state in which semiconductor layers 31, 32, and 36 are exposed by partially removing the insulating layer 38 to visually illustrate each of the components of the light emitting element 30. However, as will be described below, the insulating layer 38 may be disposed to surround the outer surfaces of the semiconductor layers 31, 32, and 36.

Specifically, the first semiconductor layer 31 may be an n-type semiconductor. For example, in case that the light emitting element 30 emits light of a blue wavelength band, the first semiconductor layer 31 may include a semiconductor material having a chemical formula of AlₓGa_{y}In_{1-x-y}N (0≤x≤1, 0≤y≤1, 0≤x+y≤1). For example, it may be any one or more of n-type doped AlGaInN, GaN, AlGaN, InGaN, AlN and InN. The first semiconductor layer 31 may be doped with an n-type dopant. For example, the n-type dopant may be Si, Ge, Sn, or the like. In an embodiment, the first semiconductor layer 31 may be n-GaN doped with n-type Si. The length of the first semiconductor layer 31 may have a range of about 1.5 μm to about 5 but is not limited thereto.

The second semiconductor layer 32 is disposed on the active layer 36 to be described below. The second semiconductor layer 32 may be a p-type semiconductor. For example, in case that the light emitting element 30 emits light of a blue or green wavelength band, the second semiconductor layer 32 may include a semiconductor material having a chemical formula of AlₓGa_{y}In_{1-x-y}N (0≤x≤1, 0≤y≤1, 0≤x+y≤1). For example, it may be any one or more of p-type doped AlGaInN, GaN, AlGaN, InGaN, AlN and InN. The second semiconductor layer 32 may be doped with a p-type dopant. For example, the p-type dopant may be Mg, Zn, Ca, Se, Ba, or the like. In an embodiment, the second semiconductor layer 32 may be p-GaN doped with p-type Mg. The length of the second semiconductor layer 32 may have a range of about 0.05 μm to about 0.10 but is not limited thereto.

Although FIG. 5 illustrates that the first semiconductor layer 31 and the second semiconductor layer 32 are formed as a layer, the disclosure is not limited thereto. According to some embodiments, depending on the material of the active layer 36, the first semiconductor layer 31 and the second semiconductor layer 32 may further include a larger number of layers such as a clad layer or a tensile strain barrier reducing (TSBR) layer.

The active layer 36 is disposed between the first semiconductor layer 31 and the second semiconductor layer 32. The active layer 36 may include a material having a single or multiple quantum well structure. In case that the active layer 36 includes a material having a multiple quantum well structure, quantum layers and well layers may be stacked each other alternately. The active layer 36 may emit light by combination of electron-hole pairs according to an electrical signal applied through the first semiconductor layer 31 and the second semiconductor layer 32. For example, in case that the active layer 36 emits light of a blue wavelength band, a material such as AlGaN or AlGaInN may be included. In particular, in case that the active layer 36 has a multiple quantum well structure in which quantum layers and well layers are alternately stacked each other, the quantum layer may include a material such as AlGaN or AlGaInN, and the well layer may include a material such as GaN or AlInN. In an embodiment, the active layer 36 may include AlGaInN as a quantum layer and AlInN as a well layer, and the active layer 36 may emit blue light having a central wavelength band of about 450 nm to about 495 nm.

However, the disclosure is not limited thereto, and the active layer 36 may have a structure in which semiconductor materials having large band gap energy and semiconductor materials having small band gap energy are alternately stacked each other, and may include other Group III to V semiconductor materials according to the wavelength band of the emitted light. The light emitted by the active layer 36 is not limited to light of a blue wavelength band, but the active layer 36 may also emit light of a red or green wavelength band in some embodiments. The length of the active layer 36 may have a range of about 0.05 μm to about 0.10 μm, but is not limited thereto.

Light emitted from the active layer 36 may be emitted to side surfaces as well as the outer surface of the light emitting element 30 in a longitudinal direction. The directionality of light emitted from the active layer 36 is not limited to a direction.

The electrode layer 37 may be an ohmic contact electrode. However, the disclosure is not limited thereto, and the electrode layer 37 may be a Schottky contact electrode. The light emitting element 30 may include at least one electrode layer 37. Although FIG. 5 illustrates that the light emitting element 30 includes an electrode layer 37, the disclosure is not limited thereto. In some embodiments, the light emitting element 30 may include a larger number of electrode layers 37 or none. The following description of the light emitting element 30 may be equally applied even if the number of electrode layers 37 is different or other structures are further included.

In the display device 10 according to an embodiment, in case that the light emitting element 30 is electrically connected to an electrode or a contact electrode, the electrode layer 37 may reduce the resistance between the light emitting element 30 and the electrode or contact electrode. The electrode layer 37 may include a conductive metal. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). Further, the electrode layer 37 may include an n-type or p-type doped semiconductor material. The length of the electrode layer 37 may have a range of about 0.05 μm to about 0.10 μm, but is not limited thereto.

The insulating film 38 is arranged to surround the outer surfaces of the semiconductor layers and electrode layers described above. In an embodiment, the insulating film 38 may be arranged to surround at least the outer surface of the active layer 36 and extend in the extension direction of the light emitting element 30. The insulating film 38 may function to protect the members. For example, the insulating film 38 may be formed to surround side surfaces of the members to expose ends of the light emitting element 30 in the longitudinal direction.

Although FIG. 5 illustrates that the insulating film 38 extends in the longitudinal direction of the light emitting element 30 to cover the side surface of the light emitting element ED ranging from the first semiconductor layer 31 to the electrode layer 37, the disclosure is not limited thereto. The insulating layer 38 may include the active layer 36 to cover only the outer surfaces of some semiconductor layers, or may cover only a portion of the outer surface of the electrode layer 37 to partially expose the outer surface of each electrode layer 37. Further, in a cross-sectional view, the insulating film 38 may have a top surface, which is rounded in a region adjacent to at least one end of the light emitting element 30.

The thickness of the insulating film 38 may have a range of about 10 nm to 1.0 but is not limited thereto. The thickness of the insulating film 38 may be about 40 nm.

The insulating layer 38 may include a material having insulating properties, such as silicon oxide (SiOₓ), silicon nitride (SiNₓ), silicon oxynitride (SiOₓN_{y}), aluminum nitride (AlNₓ), and aluminum oxide AlₓO_{y}). Accordingly, it is possible to prevent an electrical short circuit that may occur in case that the active layer 36 directly contacts the electrode through which the electrical signal is transmitted to the light emitting element 30. In addition, since the insulating film 38 includes the active layer 36 to protect the outer surface of the light emitting element 30, it is possible to prevent degradation in luminous efficiency.

Further, in some embodiments, the insulating film 38 may have an outer surface which is surface-treated. In case that the display device 10 is manufactured, the light emitting elements 30 may be aligned by being sprayed on the electrodes in a state of being dispersed in ink. Here, the surface of the insulating film 38 may be treated to have hydrophobic property or hydrophilic property in order to keep the light emitting elements ED dispersed without being aggregated with other adjacent light emitting elements ED in the ink.

The light emitting element 30 may have a length h of about 1 μm to about 10 μm or about 2 μm to about 6 μm, or about 3 μm to about 5 μm. Further, a diameter of the light emitting element 30 may have a range of about 30 nm to about 700 nm, and an aspect ratio of the light emitting element 30 may be about 1.2 to about 100. However, the disclosure is not limited thereto, and the light emitting elements 30 included in the display device 10 may have different diameters according to a difference in composition of the active layer 36. The diameter of the light emitting element 30 may have a range of about 500 nm.

The shape and material of the light emitting element 30 are not limited to those of FIG. 5. In some embodiments, the light emitting element 30 may include a larger number of layers, or may have a different shape.

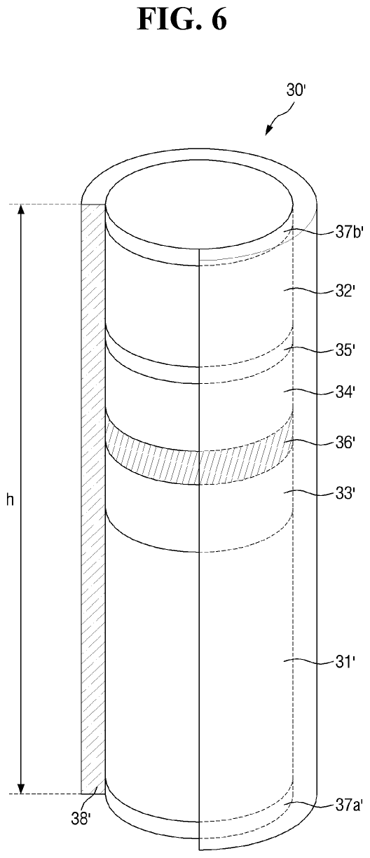

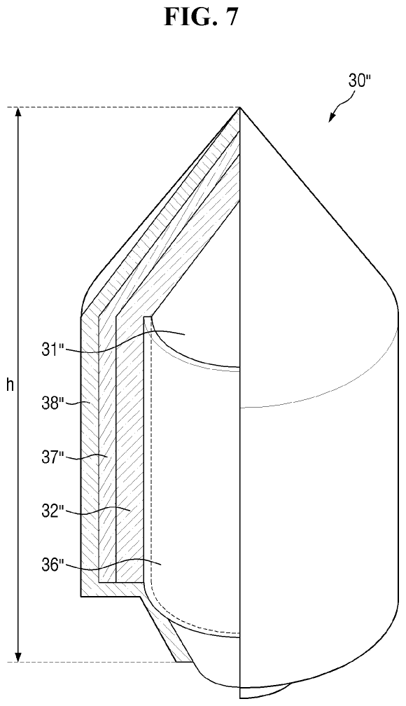

FIGS. 6 and 7 are schematic diagrams of a light emitting element according to another embodiment.

First, referring to FIG. 6, a light emitting element 30′ according to an embodiment may further include a third semiconductor layer 33′ disposed between a first semiconductor layer 31′ and an active layer 36′, and a fourth semiconductor layer 34′ and a fifth semiconductor layer 35′ disposed between the active layer 36′ and a second semiconductor layer 32′. The light emitting element 30′ of FIG. 6 is different from that of the embodiment of FIG. 5 in that semiconductor layers 33′, 34′ and 35′ and electrode layers 37a′ and 37b′ are further arranged, and the active layer 36′ contains different elements. In the following description, redundant description will be omitted while focusing on differences.

As described above, the active layer 36 of the light emitting element 30 of FIG. 5 may include nitrogen (N), and may emit blue or green light. In contrast, in the light emitting element 30′ of FIG. 6, the active layer 36′ and other semiconductor layers may each be a semiconductor including at least phosphorus (P). For example, the light emitting element 30′ according to the embodiment may emit red light having a central wavelength band in a range of about 620 nm to about 750 nm. However, it should be understood that the central wavelength band of red light is not limited to the above-mentioned range, and includes all wavelength ranges that can be recognized as red in the art.

Specifically, the first semiconductor layer 31′ may be an n-type semiconductor layer and may include a semiconductor material having a chemical formula of InₓAl_{y}Ga_{1-x-y}P (0≤x≤1, 0≤y≤1, 0≤x+y≤1). For example, the first semiconductor layer 31′ may be any one or more of InAlGaP, GaP, AlGaP, InGaP, AlP, and InP doped with n-type. In an embodiment, the first semiconductor layer 31′ may be n-AlGaInP doped with n-type Si.

The second semiconductor layer 32′ may be a p-type semiconductor layer and may include a semiconductor material having a chemical formula of InₓAl_{y}Ga_{1-x-y}P (0≤x≤1, 0≤y≤1, 0≤x+y≤1). For example, the second semiconductor layer 32′ may be any one or more of InAlGaP, GaP, AlGaNP, InGaP, AlP, and InP doped with p-type. In an embodiment, the second semiconductor layer 32′ may be p-GaP doped with p-type Mg.

The active layer 36′ may be disposed between the first semiconductor layer 31′ and the second semiconductor layer 32′. The active layer 36′ may emit light of a specific wavelength band by including a material having a single or multiple quantum well structure. In case that the active layer 36′ has a multiple quantum well structure in which quantum layers and well layers are alternately stacked each other, the quantum layer may include a material such as AlGaP or AlInGaP, and the well layer may include a material such as GaP or AlInP. In an embodiment, the active layer 36′ may include AlGaInP as a quantum layer and AlInP as a well layer to emit red light having a central wavelength band of about 620 nm to about 750 nm.

The light emitting element 30′ of FIG. 6 may include a clad layer disposed adjacent to the active layer 36′. As shown in the drawing, below and above the active layer 36′, the third semiconductor layer 33′ and the fourth semiconductor layer 34′ disposed between the first semiconductor layer 31′ and the second semiconductor layer 32′ may be clad layers.

The third semiconductor layer 33′ may be disposed between the first semiconductor layer 31′ and the active layer 36′. The third semiconductor layer 33′ may be an n-type semiconductor, similar to the first semiconductor layer 31′. For example, the third semiconductor layer 33′ may include a semiconductor material represented by a chemical formula of InₓAl_{y}Ga_{1-x-y}P (0≤x≤1, 0≤y≤1, 0≤x+y≤1). In an embodiment, the first semiconductor layer 31′ may be n-AlGaInP, and the third semiconductor layer 33′ may be n-AlInP. However, the disclosure is not limited thereto.

The fourth semiconductor layer 34′ may be disposed between the active layer 36′ and the second semiconductor layer 32′. The fourth semiconductor layer 34′ may be a p-type semiconductor, similar to the second semiconductor layer 32′. For example, the fourth semiconductor layer 34′ may include a semiconductor material represented by a chemical formula of InₓAl_{y}Ga_{1-x-y}P (0≤x≤1, 0≤y≤1, 0≤x+y≤1). In an embodiment, the second semiconductor layer 32′ may be p-GaP, and the fourth semiconductor layer 34′ may be p-AlInP.

The fifth semiconductor layer 35′ may be disposed between the fourth semiconductor layer 34′ and the second semiconductor layer 32′. The fifth semiconductor layer 35′ may be a p-type doped semiconductor, similar to the second semiconductor layer 32′ and the fourth semiconductor layer 34′. In some embodiments, the fifth semiconductor layer 35′ may function to reduce a difference in lattice constant between the fourth semiconductor layer 34′ and the second semiconductor layer 32′. For example, the fifth semiconductor layer 35′ may be a tensile strain barrier reducing (TSBR) layer. For example, the fifth semiconductor layer 35′ may include p-GaInP, p-AlInP, p-AlGaInP, or the like, but is not limited thereto. In addition, the third semiconductor layer 33′, the fourth semiconductor layer 34′, and the fifth semiconductor layer 35′ may have lengths in a range of about 0.08 μm to about 0.25 μm, but are not limited thereto.

The first electrode layer 37a′ and the second electrode layer 37b′ may be disposed on the first semiconductor layer 31′ and the second semiconductor layer 32′, respectively. The first electrode layer 37a′ may be disposed on the bottom surface of the first semiconductor layer 31′, and the second electrode layer 37b′ may be disposed on the top surface of the second semiconductor layer 32′. However, the disclosure is not limited thereto, and at least one of the first electrode layer 37a′ and the second electrode layer 37b′ may be omitted. For example, in the light emitting element 30′, the first electrode layer 37a′ may not be provided on the bottom surface of the first semiconductor layer 31′, and only a second electrode layer 37b′ may be provided on the top surface of the second semiconductor layer 32′.

Referring to FIG. 7, a light emitting element 30″ may have a shape extending in a direction, and may have a side surface with a partially inclined shape. For example, the light emitting element 30″ according to an embodiment may have a partially conical shape.

The light emitting element 30″ may be formed such that layers are not stacked each other in a direction, and each layer surrounds the outer surface of any other layer. The light emitting element 30″ may include at least regions of a semiconductor core extending in a direction and an insulating film 38″ formed to surround the semiconductor core. The semiconductor core may include a first semiconductor layer 31″, an active layer 36″, a second semiconductor layer 32″, and an electrode layer 37″.

The first semiconductor layer 31″ may be formed to extend in a direction and to have ends inclined toward the center. The first semiconductor layer 31″ may include a body portion having a rod shape or a cylindrical shape, and end portions whose side surfaces have inclined shapes, and which are formed above or below the body portion, respectively. The upper end portion of the body portion may have a steeper inclination than the lower end portion.

The active layer 36″ is disposed to surround the outer surface of the body portion of the first semiconductor layer 31″. The active layer 36″ may have an annular shape extending in a direction. The active layer 36″ may not be formed on the upper end portion and the lower end portion of the first semiconductor layer 31″. However, the disclosure is not limited thereto. Light emitted from the active layer 36″ may be emitted not only from ends of the light emitting element 30″ in the longitudinal direction, but also from side surfaces of the light emitting element 30″ with respect to the longitudinal direction. Compared to the light emitting element 30 of FIG. 5, the light emitting element 30″ of FIG. 7 has a large area of the active layer 36″ so that a larger amount of light may be emitted.

The second semiconductor layer 32″ is disposed to surround the outer surface of the active layer 36″ and the upper end portion of the first semiconductor layer 31″. The second semiconductor layer 32″ may include an annular body portion extending in a direction and an upper end portion formed to be inclined at a side surface. For example, the second semiconductor layer 32″ may directly contact the parallel side surface of the active layer 36″ and the inclined upper end portion of the first semiconductor layer 31″. However, the second semiconductor layer 32″ is not formed on the lower end portion of the first semiconductor layer 31″.

The electrode layer 37″ is disposed to surround the outer surface of the second semiconductor layer 32″. The shape of the electrode layer 37″ may be substantially the same as that of the second semiconductor layer 32″. The electrode layer 37″ may entirely contact the outer surface of the second semiconductor layer 32″.

The insulating film 38″ may be disposed to surround outer surfaces of the electrode layer 37″ and the first semiconductor layer 31″. The insulating film 38″ may directly contact the electrode layer 37″, the lower end portion of the first semiconductor layer 31″, and the exposed lower end portions of the active layer 36″ and the second semiconductor layer 32″.

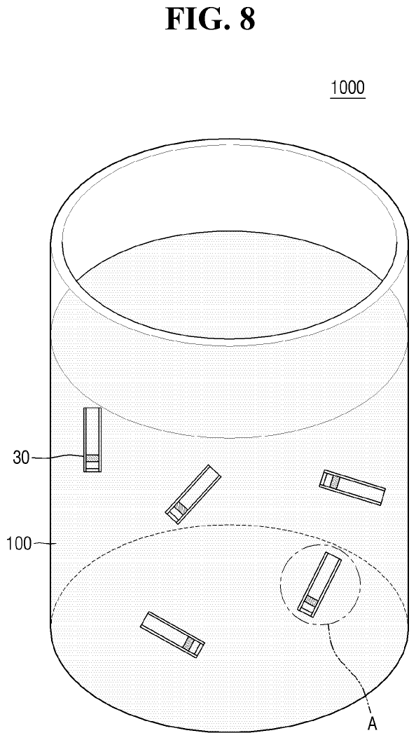

As described above, the light emitting element 30 may be sprayed onto the electrodes 21 and 22 while being dispersed in a light emitting element solvent 100 (see FIG. 8), and may be disposed between the electrodes 21 and 22 by the process of applying the alignment signal to the electrodes 21 and 22. In some embodiments, the light emitting element 30 may be prepared while being dispersed in the light emitting element solvent 100, and may be sprayed onto each of the electrodes 21 and 22 by the inkjet printing process. In case that the alignment signal is applied to each of the electrodes 21 and 22, an electric field is formed thereon, and the light emitting element 30 may receive a dielectrophoretic force by the electric field. The light emitting element 30 to which the dielectrophoretic force is transmitted may be disposed on the first electrode 21 and the second electrode 22 while the orientation direction and position thereof are being changed.

As described above, the light emitting element 30 may include the semiconductor layers and may be made of materials having a specific gravity higher than that of the light emitting element solvent 100. The light emitting element 30 may gradually precipitate while being maintained in a dispersed state in the light emitting element solvent 100 for a period of time (e.g., a predetermined or selected period of time). In order to prevent this, the light emitting element solvent 100 may have a viscosity that allows a state in which the light emitting element 30 is dispersed in the ink 1000 to be maintained for a certain period of time or more, and at the same time allows the light emitting element solvent 100 to be ejected through a nozzle in the inkjet printing process.

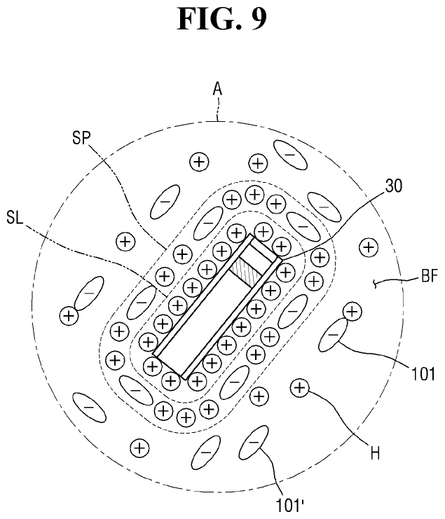

FIG. 8 is a schematic diagram of a light emitting element ink according to an embodiment. FIG. 9 is a schematic diagram illustrating the light emitting element dispersed in a light emitting element ink according to an embodiment. FIG. 9 is a schematic diagram illustrating an enlarged view of portion A of FIG. 8.

Referring to FIGS. 8 and 9, the light emitting element ink 1000 according to an embodiment includes the light emitting element solvent 100 and the light emitting element 30 dispersed in the light emitting element solvent 100. Since the description of the light emitting element 30 is the same as the above description, the light emitting element solvent 100 will be described in detail hereinafter.

The light emitting element solvent 100 may be an organic solvent that stores the light emitting element 30 in a dispersed state and does not react with the light emitting element 30. Further, the light emitting element solvent 100 may have a viscosity that allows the light element solvent 100 to be ejected through the nozzle of an inkjet printing apparatus. Solvent molecules 101 may disperse the light emitting element 30 while surrounding the surface of the light emitting element 30.

In this specification, “light emitting element solvent 100” may be understood to mean a solvent in which the light emitting element 30 may be dispersed, or a medium thereof, and “solvent molecule 101” may be understood to refer to a molecule forming the light emitting element solvent 100. As will be described below, “light emitting element solvent 100” may be understood as a liquid medium including “solvent molecules 101” and ionic solvent molecules obtained by dissociation of some of them. However, these terms may not be necessarily used separately, and in some embodiments, the terms “light emitting element solvent 100” and “solvent molecule 101” may be used interchangeably and may mean substantially the same thing.

Some of the solvent molecules 101 may be dissociated and exist in a charged ionic state in the light emitting element solvent 100 due to breaking of some of intramolecular bonds, and they may form a single micelle structure while surrounding the surface of the light emitting element 30. Charged solvent molecular ions 101′ and H may form a double layer between the surface of the light emitting element 30 and the bulk fluid BF of the light emitting element solvent 100.

The light emitting elements 30 may be dispersed in the bulk fluid in a state where neighboring solvent molecules 101 or the ions 101′ and H obtained by dissociation of the solvent molecules 101 are attached or adsorbed to the surfaces thereof. The light emitting element 30 may have a surface charge or a zeta potential measured between the bulk fluid and the slipping plane of the double layer formed by the charged ions 101′ and H. The zeta potential, which is the potential of the double layer formed by the solvent molecules 101 and the ions 101′ and H obtained by dissociation thereof on the surface of the light emitting element 30 dispersed in the light emitting element solvent 100, may be understood as the surface charge of the light emitting element 30 surrounded by ions or the zeta potential of the light emitting element 30. Hereinafter, this will be referred to as the zeta potential of the light emitting element 30.

The light emitting element 30 may have the zeta potential depending on the concentration gradient of the solvent molecule 101 and the ions 101′ and H obtained by dissociation thereof in the double layer. The zeta potentials of the light emitting elements 30 dispersed in the light emitting element solvent 100 may have normal distribution, and the average zeta potential thereof may be measured. In case that the average of the absolute values of the zeta potentials of the light emitting elements 30 (for example, the absolute value of the average value of the zeta potentials of the light emitting elements 30) is small, some of the light emitting elements 30 may have zeta potentials having opposite signs. In case that the light emitting element 30 is disposed on the electrodes 21 and 22 by an electric field, an attractive force may act between the light emitting elements 30 depending on the zeta potentials, and some light emitting elements 30 may be disposed on the electrodes 21 and 22 while being aggregated with other adjacent light emitting elements 30. In case that the light emitting elements 30 are disposed on the electrodes 21 and 22 in an aggregated state, the contact between the contact electrode 26 and the light emitting element 30 may become poor or a short circuit may occur between the electrodes 21 and 22. In case that the electrodes 21 and 22 are short-circuited by the light emitting elements 30, an electric signal may not be transmitted to other light emitting elements 30 and emission failure may occur in the corresponding sub-pixel PXn.

In case that the average of the absolute values of the zeta potentials of the light emitting elements 30 is large, the zeta potentials of the light emitting elements 30 in the light emitting element ink 1000 may have a same sign, and a repulsive force may act between the light emitting elements 30 in case that they are disposed on the electrodes 21 and 22 by the electric field. Accordingly, the light emitting elements 30 may be disposed on the electrodes 21 and 22 while being spaced apart from each other without aggregation.

The light emitting element ink 1000 according to an embodiment may include the light emitting element solvent 100 that allows the average of the absolute values of the zeta potentials of the light emitting elements 30 to be large. The light emitting element solvent 100 may have a physical property that allows the zeta potential of the light emitting element 30 to have the above-described value, and may prevent the aggregation of the light emitting elements 30 during the manufacturing process of the display device 10 by using the light emitting element ink 1000.

In an embodiment, the solvent molecule 101 of the light emitting element solvent 100 may have a relatively low pKa value, and a relatively large number of solvent molecules 101 may be dissociated and exist in an ionic state. As the amount or concentration of the ions surrounding the light emitting element 30 increases, the amount of charges in the double layer formed by the ions on the surface of the light emitting element 30 may increase, and the absolute value of the zeta potential of the light emitting element 30 may increase.

In an embodiment, the solvent molecule 101 may include a primary alcohol group having a pKa value within a range of about 7 to about 15, and may be represented by the following Chemical Formula 1 or Chemical Formula 2.

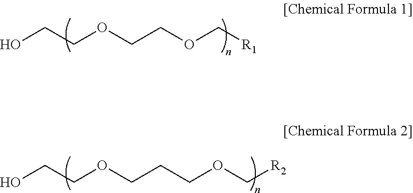

In the Chemical Formulas 1 and 2, n may be an integer of about 2 to about 10, and each of the R₁ and the R₂ may be independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

The light emitting element solvent 100 may be an organic solvent in which the solvent molecule 101 includes ethylene glycol or 1,3-propylene glycol as a repeating unit. Since the solvent molecule 101 includes the functional group as the repeating unit, the light emitting element solvent 100 may have a viscosity that allows the light emitting elements 30 to be dispersed without reacting with the solvent molecule 101 and allows ejection of the light emitting element solvent 100 using a nozzle. However, the disclosure is not limited thereto, and the solvent molecule 101 may have a structure including other functional groups.

The solvent molecule 101 may be primary alcohol in which a hydroxyl group (—OH or —CH₂OH group) is bonded to a terminal group in addition to the structure in which the functional groups are repeated. The primary alcohol may have a lower pKa value compared to a secondary or tertiary alcohol, and may have a relatively high degree of dissociation in the light emitting element solvent 100. In case that the solvent molecule 101, which is the primary alcohol is dissociated, it may be divided into hydrogen ions H (see FIG. 9) and alkoxy ions 101′ (see FIG. 9). They may be disposed to surround the surface of the light emitting element 30 while being positively charged and negatively charged, and form a micelle structure together with the light emitting element 30.

For example, the light emitting element 30 may be dispersed in the light emitting element solvent 100 in a state where the insulating film 38 is surface-treated, and the hydrogen ions H and the alkoxy ions 101′ may surround the surface of the light emitting element 30 to form a double layer. The double layer may include, in addition to a stern layer SL formed by adsorption of the hydrogen ions H on the surface of the light emitting element 30 and a slipping plane SP surrounded by the hydrogen ions H and the alkoxy ions 101′ outside the stern layer SL, a diffusion layer positioned between the slipping plane SP and the bulk fluid BF. The zeta potential of the light emitting element 30, which means the amount of charges measured on the slipping plane SP with respect to a bulk fluid point, may vary depending on the concentration of the ions 101′ and H on the slipping plane SP.

As described above, the zeta potential of the light emitting element 30 may affect the behavior of the light emitting elements 30 in the electric field. The zeta potentials of the light emitting elements 30 dispersed in the light emitting element solvent 100 may have normal distribution, and in case that the average of the absolute values of the zeta potentials is small, some of the light emitting elements 30 may have the zeta potentials having opposite signs. The attractive force may act between the light emitting elements 30 in the light emitting element solvent 100, and the light emitting elements 30 may be aggregated with each other while the positions and orientation directions thereof are being changed by the electric field.

On the other hand, in case that the light emitting element solvent 100 has a relatively low pKa value, and the concentration of the ions 101′ and H formed by dissociation of the solvent molecule 101 increases, the absolute value of the zeta potential measured on the slipping plane SP may increase. Even if the zeta potentials of the light emitting elements 30 have normal distribution, the zeta potentials thereof may have values having a same sign. Accordingly, even if the orientation directions and positions of the light emitting elements 30 are changed by the electric field, the repulsive force acts therebetween, which makes it possible to prevent the light emitting elements 30 from being aggregated on the electrodes 21 and 22.

The zeta potential of the light emitting element 30 and the pKa value of the light emitting element solvent 100 may have a specific correlation. In an embodiment, the zeta potential of the light emitting element 30 and the pKa value of the light emitting element solvent 100 may satisfy the following Equation 1.

Zeta potential (mV) of the light emitting element dispersed in the light emitting element solvent=C1*pKa+C2 [Equation 1]

“pKa” is a pKa value of the solvent molecule 101 of the light emitting element solvent 100, and “C1” and “C2” are proportional constants. For example, “C1” may be a real number of about 7 to about 18 or about 10 to about 15, or about 12. “C2” may be a real number of about −150 to about −300 or about −200 to about −250, or about −220.

As described above, in case that the pKa value of the solvent molecule 101 of the light emitting element solvent 100 is within a range of about 7 to about 15, the zeta potential of the light emitting element 30 dispersed in the light emitting element solvent 100 may have a value of about −30 mV or less. For example, in case that “C1” is about 12.1, “C2” is about −221.2, and the pKa value of the solvent molecule 101 is within a range of about 10 to about 15, the zeta potential of the light emitting element 30 dispersed in the light emitting element solvent 100 may be within a range of about −80 mV to about −50 mV. However, the pKa value of the solvent molecule 101 and the numerical ranges of C1 and C2 are example ranges, and the ranges thereof may be variously modified depending on types of the light emitting element 30 and the solvent molecules 101.

In case that the zeta potentials of the light emitting elements 30 are within the above-described range, even if the zeta potentials have normal distribution, the light emitting elements 30 may substantially have zeta potentials having a same sign. In the process of placing the light emitting elements 30, having the zeta potentials within the above range, on the electrodes 21 and 22, they may be disposed on the electrodes 21 and 22 while being spaced apart from each other without aggregation due to the repulsive force acting therebetween.

As described above, the light emitting element solvent 100 may have a viscosity that allows the light emitting elements 30 to be dispersed therein and allows ejection of the light emitting element solvent 100 using a nozzle. In case that the solvent molecule 101 is represented by Chemical Formula 1 or 2, n and R1 and R2 may be adjusted within a range in which the light emitting element solvent 100 may have a specific viscosity. In an embodiment, the light emitting element solvent 100 may have a viscosity of about 5 cP to about 80 cP or about 20 cP to about 60 cP, or about 35 cP to about 50 cp, and n and R1 and R2 of Chemical formulas 1 and 2 may be adjusted within the above range. However, the disclosure is not limited thereto.

Further, since the solvent molecule 101 has a pKa value within a certain range, the structure thereof is not limited to Chemical Formulas 1 and 2 as long as it is possible to increase the absolute value of the zeta potential of the light emitting element 30. In some embodiments, the solvent molecule 101 may have a structure in which hydrogen in a carbon chain is replaced by fluorine (F) to have a lower pKa value.

For example, the solvent molecule 101 may be represented by the following Chemical Formula 3.

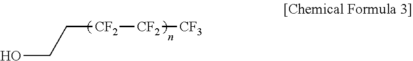

In Chemical Formula 3, n is an integer of about 1 to about 10. The solvent molecule 101 may be primary alcohol including a repeating unit of —CF₂CF₂— and having a terminal group including a —CF₃ group and a hydroxyl group (—OH or —CH₂OH). The carbon chain in which fluorine (F) having a high electron affinity is replaced may further stabilize the negative charge of the alkoxy ion (—O—) formed by separation of hydrogen of the alcohol group, and the pKa value of the solvent molecule 101 may be further lowered. Accordingly, a larger number of solvent molecules 101 exist in a dissociated ionic state in the light emitting element solvent 100, and the absolute value of the zeta potential may further increase due to the increase in the concentration of ions in the double layer of the light emitting element 30.

Further, the solvent molecule 101 does not include a primary alcohol group and an ethylene glycol group, and may include a functional group having a low pKa value so that the micelle structure including the light emitting element 30 may have a zeta potential whose absolute value is large. In an embodiment, the solvent molecule 101 includes a 1,3-dicarbonyl group, and may be represented by any one of the following Chemical Formulas 4 to 6.

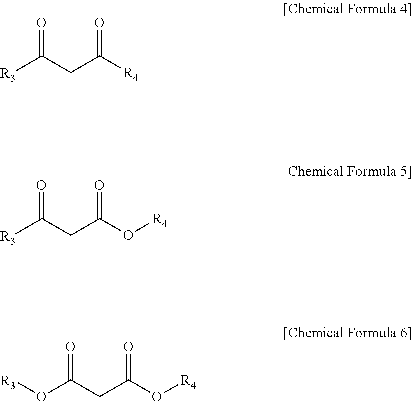

In the Chemical Formulas 4 to 6, R₃ and R₄ may be independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

The solvent molecule 101 may include the 1,3-dicarbonyl group and thus may have a pKa value within the above-described range. Carbon (—CH₂) located between two carbonyl groups (—C═O) may be stabilized by an adjacent carbonyl group (—C═O) in case that a negative charge is formed by separation of hydrogen, so that hydrogen in the carbon may have a low pKa value. Even if the solvent molecule 101 includes the structure represented by the Chemical Formulas 4 to 6, it may have a pKa value within a range similar to that of the primary alcohol, and the light emitting elements 30 in the light emitting element ink 1000 may have zeta potentials whose absolute values are large. Accordingly, the light emitting elements 30 may be disposed on the electrodes 21 and 22 without aggregation during the manufacturing process of the display device 10.

Hereinafter, a method for manufacturing the display device 10 according to an embodiment will be described.

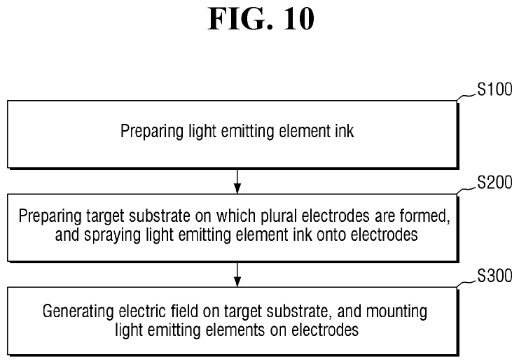

FIG. 10 is a schematic flowchart showing a method for manufacturing a display device according to an embodiment.

Referring to FIG. 10, the method for manufacturing the display device 10 according to an embodiment may include preparing the light emitting element ink 1000 including the light emitting element solvent 100 and the light emitting element 30 (S100), preparing a target substrate on which the electrodes 21 and 22 are formed and spraying the light emitting element ink 1000 onto the electrodes 21 and 22 (S200), and generating an electric field on the target substrate and mounting the light emitting element 30 on the first electrode 21 and the second electrode 22 (S300).

The light emitting element 30 may be prepared while being dispersed in the light emitting element ink 1000, and may be ejected onto the electrodes 21 and 22 by an inkjet printing process. In case that the light emitting element ink 1000 is ejected onto the electrodes 21 and 22, an electric field is generated on the target substrate or the electrodes 21 and 22 so that the light emitting elements 30 are mounted on the electrodes 21 and 22. In accordance with an embodiment, since the light emitting element solvent 100 of the light emitting element ink 1000 has a low pKa value, the light emitting elements 30 may have zeta potentials whose absolute values are large, and may be mounted on the electrodes 21 and 22 while being spaced apart from each other due to the repulsive force acting therebetween in case that the positions thereof are changed by the electric field.

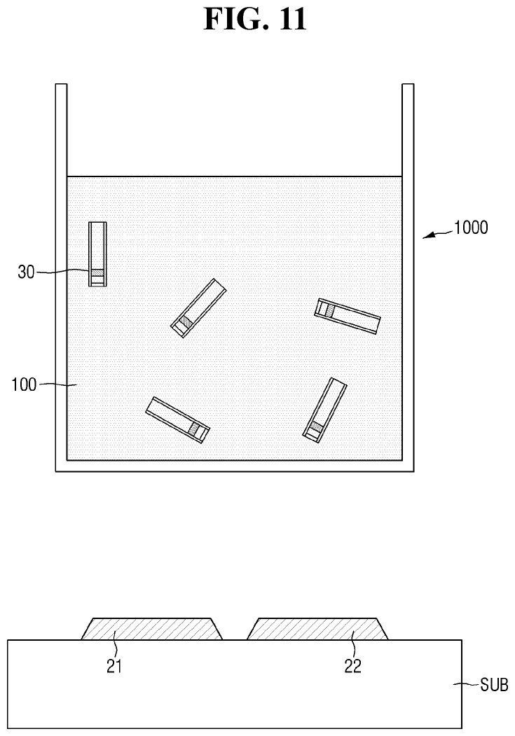

FIGS. 11 to 14 are schematic views illustrating a part of a process of manufacturing a display device according to an embodiment.

First, referring to FIG. 11, the light emitting element ink 1000 including the light emitting element 30 and the light emitting element solvent 100, and a target substrate SUB on which the first electrode 21 and the second electrode 22 are disposed are prepared. Although FIG. 11 illustrates that a pair of electrodes is disposed on the target substrate SUB, a larger number of electrode pairs may be disposed on the target substrate SUB. The target substrate SUB may include circuit elements disposed thereon in addition to the first substrate 11 of the above-described display device 10. In the following, the illustration thereof will be omitted for simplicity of description.

The light emitting element ink 1000 may include the light emitting element solvent 100 and the light emitting element 30 dispersed therein. In the light emitting element ink 1000 stored in a container, the solvent molecules 101 may be dissociated and exist in an ionic state, and the light emitting element 30 may be dispersed with a zeta potential whose absolute value is large. In the light emitting element ink 1000 that is not yet ejected through a nozzle, the light emitting elements 30 may be maintained in a dispersed state for a long period of time due to the repulsive force acting therebetween depending on the zeta potentials between other adjacent light emitting elements 30.

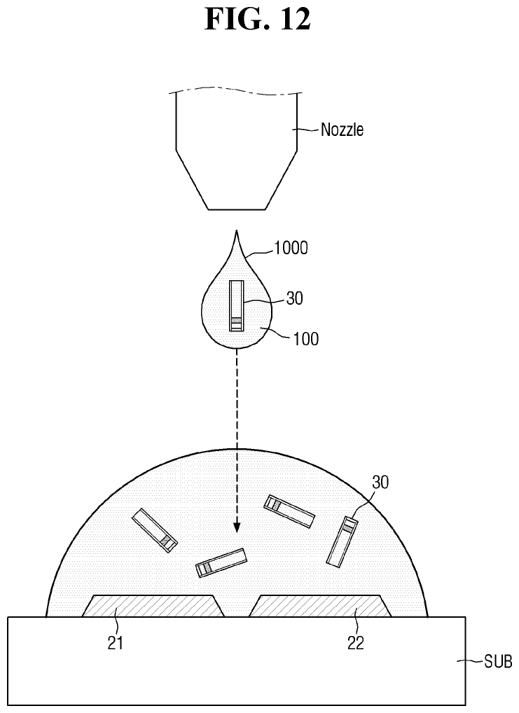

Referring to FIG. 12, the light emitting element ink 1000 is sprayed onto the first electrode 21 and the second electrode 22 on the target substrate SUB. In an embodiment, the light emitting element ink 1000 may be sprayed onto the electrodes 21 and 22 by the printing process using the inkjet printing apparatus. The light emitting element ink 1000 may be sprayed through the nozzle of the inkjet head included in the inkjet printing apparatus. The light emitting element ink 1000 may flow along an inner flow path in the inkjet head and may be ejected onto the target substrate SUB through the nozzle.

The light emitting element ink 1000 ejected from the nozzle may be mounted on the electrodes 21 and 22 disposed on the target substrate SUB. The light emitting element 30 may have a shape extending in a direction, and may be dispersed in a state where the extension direction in the light emitting element ink 1000 in a random orientation direction.

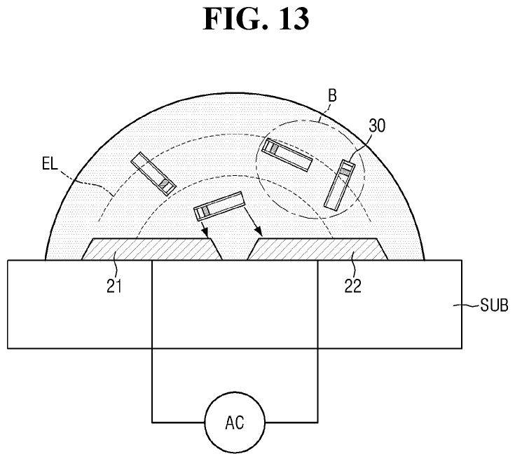

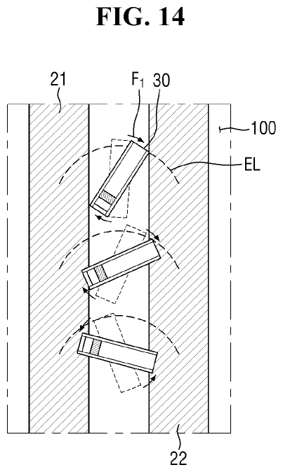

Referring to FIGS. 13 and 14, in case that the light emitting element ink 1000 including the light emitting element 30 is sprayed onto the target substrate SUB, an alignment signal is applied to the electrodes 21 and 22 to generate an electric field EL on the target substrate SUB. The light emitting elements 30 dispersed in the light emitting element solvent 100 may receive a dielectrophoretic force by the electric field EL, and may be disposed on the electrodes 21 and 22 while the orientation directions and positions thereof are being changed.

In case that the electric field EL is generated on the target substrate SUB, the light emitting element 30 may receive a dielectrophoretic force F₁. In some embodiments, in case that the electric field EL is generated on the target substrate SUB in parallel to the top surface of the target substrate SUB, the light emitting element 30 may be disposed on the first electrode 21 and the second electrode 22 while being aligned such that the extension direction thereof is parallel to the target substrate SUB. The light emitting element 30 may move toward the electrodes 21 and 22 from an initially dispersed position (dotted line portion in FIG. 14) by the dielectrophoretic force F₁. Ends of the light emitting element 30 may be respectively disposed on the first electrode 21 and the second electrode 22 while the positions and orientation directions thereof are being changed by the electric field EL.

In case that the positions of the light emitting elements 30 are changed, the attractive force may act between the light emitting elements 30 depending on the zeta potential of the light emitting elements 30 and, thus, they may be disposed on the electrodes 21 and 22 in an aggregated state. However, since the light emitting element solvent 100 according to an embodiment has a low pKa value, the light emitting element 30 dispersed therein may have a zeta potential with a large absolute value, and the repulsive force may act between the light emitting elements 30 in case that the positions thereof are changed by the electric field EL. Since the light emitting elements 30 are disposed on the electrodes 21 and 22 in a state where the repulsive force acts therebetween, they may be spaced apart from each other without aggregation.

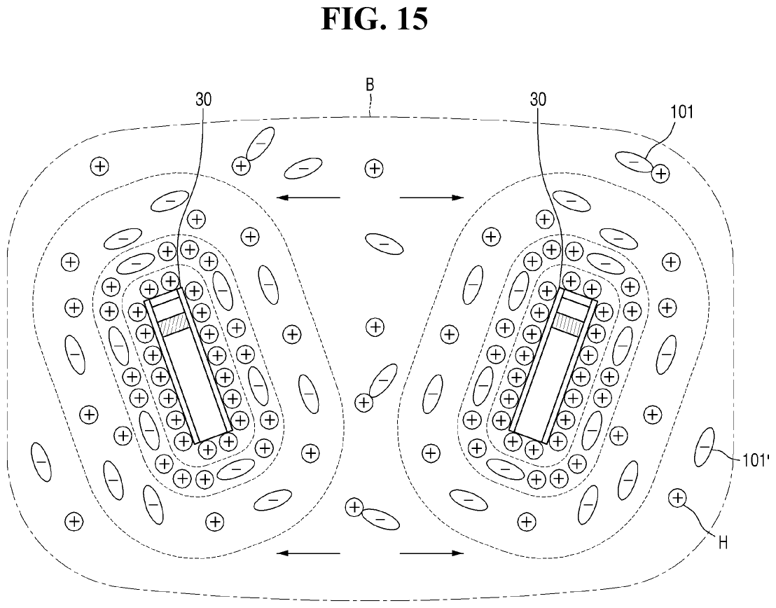

FIG. 15 is a schematic diagram illustrating behavior of a light emitting element in a light emitting element ink according to an embodiment. FIG. 15 illustrates the behavior of different light emitting elements 30 in the light emitting element solvent 100 where the electric field EL is generated, and is a schematic enlarged view of portion B of FIG. 13.

Referring to FIG. 15, the solvent molecules 101 of the light emitting element solvent 100 may be partially dissociated and surround the light emitting elements 30 in a state of the ions 101′ and H. As described above, the solvent molecule 101 is dissociated into positively charged ions and negatively charged ions, and they form a double layer around the light emitting element 30 so that the light emitting element 30 may have a zeta potential. Since the zeta potentials of the light emitting elements 30 have a large absolute value, the zeta potentials of different light emitting elements 30 may have a same sign even if the zeta potentials have normal distribution. The light emitting elements 30 of which positions are changed by the electric field EL may be disposed on the electrodes 21 and 22 while repelling each other by the repulsive force caused by the zeta potentials therebetween. The light emitting elements 30 dispersed in the light emitting element solvent 100 may be aligned on the electrodes 21 and 22 while being spaced apart from each other without substantial aggregation.

As described above, the zeta potential of the light emitting element 30 may have a specific correlation with the pKa value of the solvent molecule 101 of the light emitting element solvent 100. Similarly, the aggregation ratio of the light emitting elements 30 may have a correlation with the average value of the zeta potentials of the light emitting elements 30.

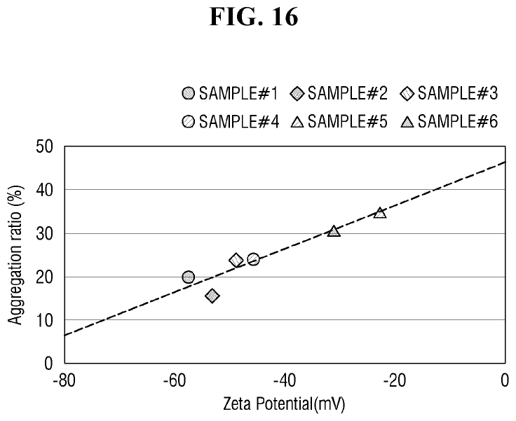

FIG. 16 is a schematic graph illustrating the aggregation ratio of light emitting elements with respect to the zeta potential of the light emitting element in a light emitting element ink according to an embodiment. FIG. 16 illustrates the zeta potential of the light emitting element 30 depending on the type of the light emitting element solvent 100 and the aggregation ratio of the light emitting element 30 according thereto.

In FIG. 16, solvent samples SAMPLE #1, SAMPLE #2, SAMPLE #3, and SAMPLE #4 including a primary alcohol group and solvent samples SAMPLE #5 and SAMPLE #6 including a secondary alcohol group were prepared, and the light emitting element 30 was dispersed therein and aligned on the electrodes 21 and 22. The zeta potential (mV) of the light emitting element 30 was measured in different solvent samples, and the light emitting elements 30 were disposed on the electrodes 21 and 22. The number of light emitting elements 30 disposed in an aggregated state among the entire light emitting elements 30 disposed on the electrodes 21 and 22 was measured and illustrated, as the aggregation ratio (%) according to the zeta potential of the light emitting element 30, in a graph. The aggregation ratio of the light emitting elements 30 was calculated based on the number of the aggregated light emitting elements 30 among about 1000 or more light emitting elements 30. The average value of the zeta potentials of the light emitting elements 30 was calculated and illustrated, as the zeta potential of the light emitting element 30, in the graph.

The first to fourth solvent samples SAMPLE #1, SAMPLE #2, SAMPLE #3, and SAMPLE #4 include the primary alcohol group and have pKa values within a range of about 7 to about 15. The fifth and sixth solvent samples SAMPLE #5 and SAMPLE #6 include the secondary alcohol group and have pKa values of about 15 or more.

Referring to FIG. 16, the zeta potentials of the light emitting elements 30 dispersed in the first to fourth solvent samples SAMPLE #1, SAMPLE #2, SAMPLE #3, and SAMPLE #4 including the primary alcohol group are lower than those of the fifth and sixth solvent samples SAMPLE #5 and SAMPLE #6 including the secondary alcohol group. However, since the zeta potential of the light emitting element 30 is measured as a negative value, the absolute value of the zeta potential of the light emitting element 30 dispersed in the solvent molecule including the primary alcohol group is larger than that of the light emitting element 30 dispersed in the solvent molecule including the secondary alcohol group. Since the solvent molecule including the primary alcohol group has a lower pKa value, the concentration of dissociated ions in the solvent may further increase, and the absolute value of the zeta potential of the light emitting element 30 may further increase.

The average value of the zeta potentials of the light emitting elements 30 dispersed in the first to fourth solvent samples SAMPLE #1, SAMPLE #2, SAMPLE #3, and SAMPLE #4 may be within a range of about −70 mV to about −50 mV, and the aggregation ratio of the light emitting elements 30 may be about 20%. On the other hand, the average value of the zeta potentials of the light emitting elements 30 dispersed in the fifth and sixth solvent samples SAMPLE #5 and SAMPLE #6 may be about −20 mV, and the aggregation ratio of the light emitting elements 30 may be about 30%. As the pKa value of the solvent molecules decreases, the absolute value of the average of the zeta potentials of the dispersed light emitting elements 30 may further increase, and the aggregation ratio of the light emitting elements 30 may further decrease.

Further, the aggregation ratio of the light emitting elements 30 may be linearly proportional to the zeta potential of the light emitting elements 30. In an embodiment, the aggregation ratio and the zeta potential of the light emitting elements 30 may satisfy the following Equation 2.

Aggregation ratio (%) of light emitting element=C3*Z+C4 [Equation 2]

In Equation 2, “Z” is the zeta potential (mV) of the light emitting element 30, and “C3” and “C4” are proportional constants. For example, “C3” may be a real number of about 0.1 to about 1.0 or about 0.3 to about 0.7, or about 0.5. “C4” may be a real number of about 1.0 to about 100 or about 30 to about 70, or about 50.

As described above, in case that the pKa value of the solvent molecule 101 is within a range of about 7 to about 15 and the zeta potential of the light emitting element 30 has a value of about −50 mV or less, the aggregation ratio of the light emitting elements 30 may be about 20% or less. For example, in case that “C3” is about 0.5, “C4” is about 46.4, and the zeta potential of the light emitting element 30 is within a range of about −70 mV to about −50 mV, the aggregation ratio of the light emitting elements 30 may be within a range of about 10% to about 20%. However, the zeta potential of the light emitting element 30 and the numerical ranges of C3 and C4 are example ranges, and the ranges thereof may be variously modified depending on types of the light emitting element 30 and the solvent molecule 101.

The zeta potentials of the light emitting elements 30 may have substantially a same sign even if the zeta potentials have normal distribution, and the light emitting elements 30 may be disposed on the electrodes 21 and 22 while being spaced apart from each other without aggregation due to the repulsive force acting therebetween. Accordingly, the light emitting elements 30 may not be aggregated on the electrodes 21 and 22 and may be disposed with a relatively uniform degree of alignment. The “degree of alignment” of the light emitting elements 30 may mean a deviation of the orientation directions and mounting positions of the light emitting elements 30 aligned on the target substrate SUB. For example, in case that there is a large deviation in the orientation directions and mounting positions of the light emitting elements 30, it may be understood that the degree of alignment of the light emitting elements 30 is low. In case that there is a small deviation in the orientation directions and mounting positions of the light emitting elements 30, it may be understood that the degree of alignment of the light emitting elements 30 is high or improved.

In case that the light emitting elements 30 are mounted on the electrodes 21 and 22, the light emitting element solvent 100 of the light emitting element ink 1000 is removed.

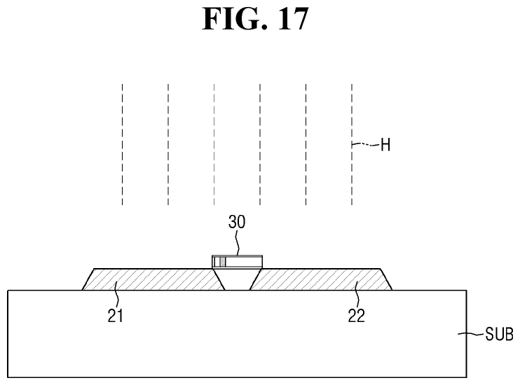

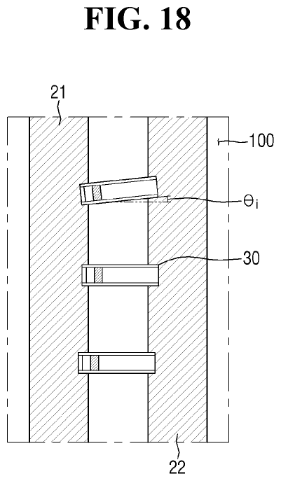

FIGS. 17 and 18 are schematic views illustrating a part of a manufacturing process of a display device according to an embodiment.

Referring to FIG. 17, the process of removing the light emitting element solvent 100 may be performed by a conventional heat treatment process. In an embodiment, the heat treatment process may be performed in a temperature range of about 200° C. to about 400° C., or about 300° C. The light emitting element solvent 100 may include the solvent molecules 101 represented by any one of the Chemical Formulas 1 to 6, and the boiling point thereof may be within the above temperature range. In case that the heat treatment process is performed within the above range, it is possible to completely remove the light emitting element solvent 100 while preventing damage to the light emitting element 30 and circuit elements.

Referring to FIG. 18, the light emitting elements 30 may be disposed on the electrodes 21 and 22 with a high degree of alignment while being dispersed in the light emitting element ink 1000 without aggregation. The repulsive force may partially act between the light emitting elements 30 even in the process of removing the light emitting element solvent 100 by the heat treatment process, so that the light emitting elements 30 may maintain an initial alignment state without aggregation. Accordingly, an acute angle Θᵢ formed between a direction in which the light emitting element 30 ultimately disposed on the electrodes 21 and 22 extends and a direction perpendicular to the direction in which the electrodes 21 and 22 extend may be very small. The acute angle Θᵢ may be about 5° or more and, thus, the acute angle formed between a direction in which the light emitting element 30 extends and the direction in which the electrodes 21 and 22 extend may be about 85° or more. For example, the acute angle formed between a direction in which the light emitting element 30 extends and the direction in which the electrodes 21 and 22 extend may be greater than or equal to about 88° and smaller than or equal to about 90°. However, the disclosure is not limited thereto.

Insulating layers and the contact electrode 26 may be formed on the light emitting element 30 and the electrodes 21 and 22, thereby manufacturing the display device 10. By performing the above processes, the display device 10 including the light emitting element 30 may be manufactured.

In accordance with an embodiment, the display device 10 on which the light emitting element 30 is disposed on the electrodes 21 and 22 may be manufactured using the light emitting element ink 1000 including the light emitting element solvent 100 and the light emitting element 30 dispersed in the light emitting element solvent 100. The light emitting element solvent 100 may have a low pKa value, and a relatively large number of solvent molecules 101 may be dissociated into ions. The light emitting elements 30 dispersed in the light emitting element solvent 100 may have zeta potentials with a large absolute value, and may be prevented from being aggregated due to the repulsive force acting in the light emitting element solvent 100. Accordingly, the light emitting elements 30 may smoothly contact the contact electrode 26 on each of the electrodes 21 and 22, and the display device 10 may reduce the defect rate of each pixel PX or sub-pixel PXn in which the light emitting elements 30 are disposed.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting element ink comprising:
a light emitting element solvent; and
a light emitting element dispersed in the light emitting element solvent and comprising:
semiconductor layers, and
an insulating film surrounding outer surfaces of the semiconductor layers,
wherein the light emitting element solvent is an organic solvent having a pKa value in a range of about 7 to about 15.

2. The light emitting element ink of claim 1, wherein a zeta potential of the light emitting element dispersed in the light emitting element solvent satisfies the following Equation 1:
Zeta potential (mV) of the light emitting element dispersed in the light emitting element solvent=C1*pKa+C2, [Equation 1]
wherein the pKa is the pKa value of the light emitting element solvent, the C1 is a real number of about 7 to about 18, and the C2 is a real number of about −150 to about −300.

3. The light emitting element ink of claim 2, wherein the zeta potential of the light emitting element dispersed in the light emitting element solvent is in a range of about −80 mV to about −50 mV.

4. The light emitting element ink of claim 3, wherein
the semiconductor layers comprise:
a first semiconductor layer;
a second semiconductor layer; and
an active layer disposed between the first semiconductor layer and the second semiconductor layer,
the insulating layer is disposed to surround at least an outer surface of the active layer.

5. The light emitting element ink of claim 2, wherein the light emitting element solvent has a viscosity in a range of about 5 cp to about 80 cp.

6. The light emitting element ink of claim 5, wherein the light emitting element solvent comprises a primary alcohol group.

7. The light emitting element ink of claim 6, wherein the light emitting element solvent comprises a compound represented by the following Chemical Formula 1 or Chemical Formula 2: 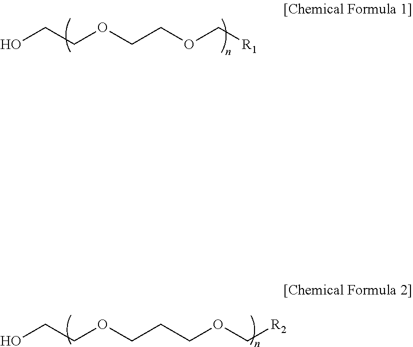
wherein the n is an integer in a range of 2 to 10, and each of the R₁ and the R₂ is independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

8. The light emitting element ink of claim 6, wherein the light emitting element solvent comprises a compound represented by the following Chemical Formula 3: 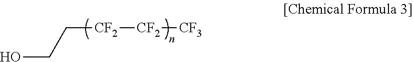
wherein the n is an integer of about 1 to about 10.

9. The light emitting element ink of claim 5, wherein the light emitting element solvent comprises a compound represented by any one of the following Chemical Formulas 4 to 6: 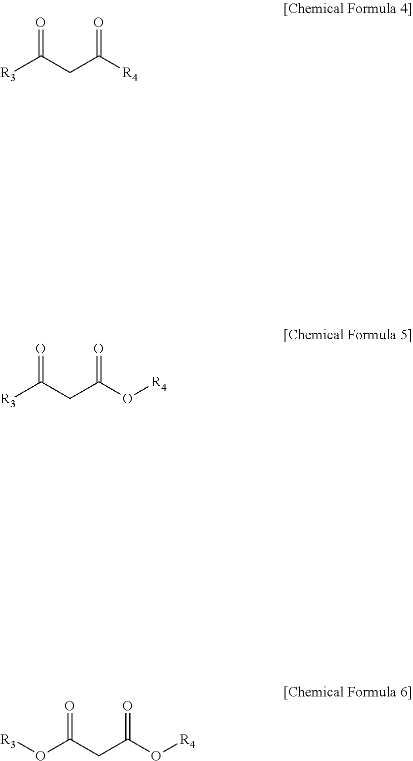
wherein each of the R₃ and R₄ is independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

10. A light emitting element solvent comprising:
a primary alcohol group having a pKa value in a range of about 7 to about 15 and comprising a compound represented by any one of the following Chemical Formula 1 to 3: 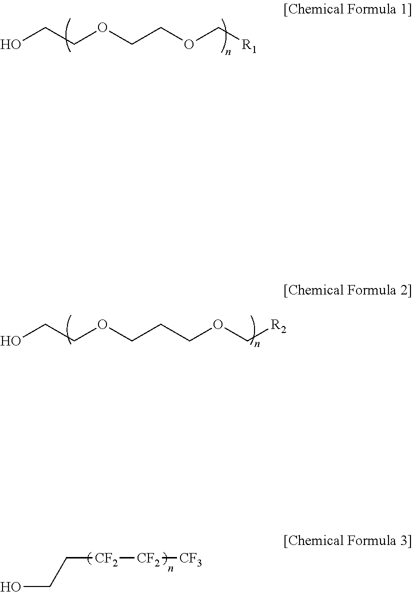
wherein the n is an integer of 2 to 10, and each of the R₁ and the R₂ is independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

11. The light emitting element solvent of claim 10, wherein the light emitting element solvent has a viscosity in a range of about 5 cp to about 80 cp.

12. A method for manufacturing a display device, comprising:
preparing a target substrate on which a first electrode and a second electrode are formed, a light emitting element comprising semiconductor layers, and a light emitting element ink comprising a light emitting element solvent in which the light emitting element is dispersed and which has a pKa value in a range of about 7 to about 15;
spraying the light emitting element ink onto the target substrate and generating an electric field on the target substrate; and
disposing the light emitting elements on the first electrode and the second electrode.

13. The method of claim 12, wherein the light emitting element solvent comprises a primary alcohol group, and a compound represented by the following Chemical Formula 1 or Chemical Formula 2: 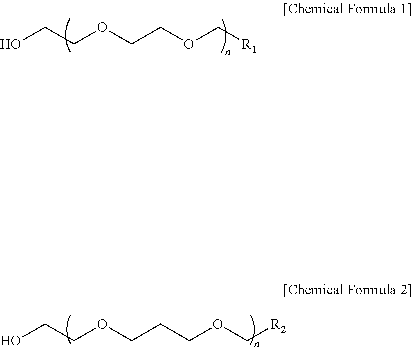
wherein the n is an integer of 2 to 10, and each of the R_{f} and the R₂ is independently any one of a C₁-C₁₀ alkyl group, a C₂-C₁₀ alkenyl group, a C₂-C₁₀ alkynyl group, a C₁-C₁₀ alkyl ether group, and a C₂-C₁₀ alkenyl ether group.

14. The method of claim 13, wherein a zeta potential of the light emitting element dispersed in the light emitting element solvent satisfies the following Equation 1:
Zeta potential (mV) of the light emitting element dispersed in the light emitting element solvent=C1*pKa+C2 [Equation 1]
wherein the pKa is the pKa value of the light emitting element solvent, the C1 is a real number of 7 to 18, and the C2 is a real number of −150 to −300.

15. The method of claim 14, wherein the zeta potential of the light emitting element dispersed in the light emitting element solvent is in a range of about −80 mV to about −50 mV.

16. The method of claim 12, wherein the disposing of the light emitting elements on the first electrode and the second electrode comprises changing a position and orientation direction of the light emitting element by the electric field.

17. The method of claim 16, wherein at least part of the light emitting elements and other part of the light emitting elements move while repelling each other by a repulsive force acting therebetween.

18. The method of claim 17, wherein an end of each of the light emitting elements is disposed on the first electrode, and another end of each of the light emitting elements is disposed on the second electrode while being spaced apart from each other.

19. The method of claim 16, wherein the disposing of the light emitting elements further comprises removing the light emitting element solvent.

20. The method of claim 19, wherein the removing of the light emitting element solvent is performed by a heat treatment process in a temperature range of about 200° C. to about 400° C.
